(19) United States
(12) Patent Application Publication
(10) Pub. No.: US 2026/0271551 A1
(43) Pub. Date: Sep. 10, 2026

(54) DISPLAY DEVICE AND ELECTRONIC DEVICE

(71) Applicant: Samsung Display Co., Ltd., Yongin-si (KR)

(72) Inventors: Dong Hyun LEE, Yongin-si (KR); Seok Hyun NAM, Yongin-si (KR); Si Joon SONG, Yongin-si (KR)

(21) Appl. No.: 19/386,109

(22) Filed: Nov. 11, 2025

(30) Foreign Application Priority Data
Mar. 5, 2025 (KR) 10-2025-0028263
Jul. 21, 2025 (KR) 10-2025-0098297

(51) Int. Cl. H10K 59/124; H10K 59/122; G09G 3/3233

(52) U.S. Cl. CPC H10K 59/124; H10K 59/122; G09G 3/3233; G09G 2300/0426; G09G 2300/0819; G09G 2300/0842; G09G 2300/0861

(57) ABSTRACT

The present disclosure relates to a display device, and more particularly, to a display device and an electronic device capable of preventing damage to a signal line by alleviating stress applied to the signal line when a display panel is bent. The display device includes: a substrate including a display area and a non-display area; a pixel located in the display area of the substrate; a trench located in the substrate, the trench overlapping a bending area of the non-display area of the substrate; and a dummy layer located in or on the substrate to overlap the trench.

### CROSS-REFERENCE TO RELATED APPLICATIONS

This application claims priority to and the benefit of Korean Patent Application No. 10-2025-0028263, filed on Mar. 5, 2025, and Korean Patent Application No.10-2025-0098297, filed on Jul. 21, 2025, in the Korean Intellectual Property Office, the entire disclosures of which are incorporated by reference herein.

### BACKGROUND

### Field

The present disclosure relates to a display device, and more particularly, to a display device and an electronic device capable of preventing damage to a signal line by alleviating stress applied to the signal line when a display panel is bent.

### Description of the Related Art

An organic light emitting display device includes a display element of which luminance is changed by a current, for example, an organic light emitting diode (OLED).

### SUMMARY

Aspects and features of embodiments of the present disclosure provide a display device and an electronic device capable of preventing damage to wiring by alleviating stress applied to wiring when a display panel is bent.

According to one or more embodiments of the present disclosure, a display device includes: a substrate including a display area and a non-display area; a pixel located in the display area of the substrate; a trench located in the substrate, the trench overlapping a bending area of the non-display area of the substrate; and a dummy layer located in or on the substrate to overlap the trench.

In one or more embodiments, the dummy layer includes a heating layer.

In one or more embodiments, the dummy layer includes amorphous silicon.

In one or more embodiments, the substrate includes: a first base layer; a barrier layer on the first base layer; and a second base layer on the barrier layer.

In one or more embodiments, the trench includes a hole penetrating at least one of the first base layer, the barrier layer, or the second base layer.

In one or more embodiments, the dummy layer overlaps the hole.

In one or more embodiments, the hole penetrates the first base layer and the barrier layer, and wherein the dummy layer is located on a bottom surface of the second base layer overlapping the hole.

In one or more embodiments, the display device further includes a planarization layer having a hole overlapping the dummy layer and located on the second base layer.

In one or more embodiments, the display device further includes a source pattern layer on the planarization layer and the second base layer.

In one or more embodiments, the source pattern layer is located closer to the substrate in the bending area than in a peripheral area outside the bending area.

In one or more embodiments, the hole of the planarization layer overlaps the hole of the substrate.

In one or more embodiments, the display device further includes a planarization layer located on the second base layer overlapping the hole, wherein the hole penetrates the first base layer, the barrier layer, and the second base layer, and wherein the dummy layer is located on a bottom surface of the planarization layer overlapping the hole.

In one or more embodiments, the display device further includes a source pattern layer located on the planarization layer overlapping the bending area.

In one or more embodiments, the display device further includes: a first planarization layer located on the substrate in the bending area; a source pattern layer located on the first planarization layer in the bending area; a second planarization layer located on the source pattern layer in the bending area; a third planarization layer located on the second planarization layer in the bending area; a pixel defining layer located on the third planarization layer in the bending area; and a spacer located on the pixel defining layer in the bending area.

In one or more embodiments, the display device further includes at least one inorganic layer located on the spacer in the bending area.

In one or more embodiments, the at least one inorganic layer is formed integrally with an inorganic layer of an encapsulation layer on the display area and the non-display area.

In one or more embodiments, the display device further includes at least one organic layer located on the spacer in the bending area.

In one or more embodiments, an electronic device includes: a display device having a display screen, wherein the display device includes: a substrate includes a display area and a non-display area; a pixel located in the display area of the substrate; a trench located in the substrate, the trench overlapping a bending area of the non-display area of the substrate; and a dummy layer located in or on the substrate overlapping the trench.

In one or more embodiments, the dummy layer includes a heating layer.

In one or more embodiments, the electronic device includes a smartphone, a tablet, a laptop, a TV, a desktop monitor, smart glasses, a smart watch, a head mounted display, and a vehicle.

In a display device according to one or more embodiments, damage to a signal line may be prevented by alleviating stress applied to the signal line when a display panel is bent.

For example, the stress applied to the signal line in the bending area may be alleviated by forming the substrate in the bending area to be thinner than the substrate in the peripheral area outside the bending area. Accordingly, damage to the signal line in the bending area may be prevented.

The effects, aspects, and features of embodiments of the present disclosure are not limited to the above-described effects, aspects, and features, and other effects, aspects, and features which are not described herein will become apparent to those skilled in the art from the following description.

### BRIEF DESCRIPTION OF THE DRAWINGS

The above and other aspects and features of embodiments of the present disclosure will become more apparent by describing in detail embodiments thereof with reference to the attached drawings, in which:

FIG. 1 is a perspective view showing a display device according to one or more embodiments;

FIG. 2 is a plan view of the display panel of FIG. 1;

FIG. 3 is a cross-sectional view illustrating a display device according to one or more embodiments;

FIG. 4 is a block diagram illustrating a display panel and a display driver according to one or more embodiments;

FIG. 5 is a circuit diagram of one pixel of a display device according to one or more embodiments;

FIG. 6 is a cross-sectional view of a display device according to one or more embodiments;

FIG. 7 is a cross-sectional view of the display device according to one or more embodiments, taken along the line I-I' of FIG. 2;

FIG. 8 is a drawing illustrating a bent state of the display device of FIG. 7;

FIG. 9 is a cross-sectional view of the display device according to another embodiment, taken along the line I-I' of FIG. 2;

FIG. 10 is a cross-sectional view of the display device according to still another embodiment, taken along the line I-I' of FIG. 2;

FIG. 11 is a cross-sectional view of the display device according to still another embodiment, taken along the line I-I' of FIG. 2;

FIG. 12 is a cross-sectional view of the display device according to still another embodiment, taken along the line I-I' of FIG. 2;

FIG. 13 is a cross-sectional view of the display device according to still another embodiment, taken along the line I-I' of FIG. 2;

FIG. 14 is a cross-sectional view of the display device according to still another embodiment, taken along the line I-I' of FIG. 2;

FIG. 15 is a cross-sectional view of the display device according to still another embodiment, taken along the line I-I' of FIG. 2;

FIG. 16 is a cross-sectional view of the display device according to still another embodiment, taken along the line I-I' of FIG. 2;

FIG. 17 is a cross-sectional view of the display device according to still another embodiment, taken along the line I-I' of FIG. 2;

FIG. 18 is a cross-sectional view of the display device according to still another embodiment, taken along the line I-I' of FIG. 2;

FIG. 19 is a cross-sectional view of the display device according to still another embodiment, taken along the line I-I' of FIG. 2;

FIG. 20 is a cross-sectional view of the display device according to still another embodiment, taken along the line I-I' of FIG. 2;

FIG. 21 is a cross-sectional view of the display device according to still another embodiment, taken along the line I-I' of FIG. 2;

FIG. 22 is a cross-sectional view of the display device according to still another embodiment, taken along the line I-I' of FIG. 2;

FIG. 23 is a cross-sectional view of the display device according to still another embodiment, taken along the line I-I' of FIG. 2;

FIG. 24 is a cross-sectional view of the display device according to still another embodiment, taken along the line I-I' of FIG. 2;

FIG. 25 is a cross-sectional view of the display device according to still another embodiment, taken along the line I-I' of FIG. 2;

FIG. 26 is a cross-sectional view of the display device according to still another embodiment, taken along the line I-I' of FIG. 2;

FIG. 27 is a cross-sectional view of the display device according to still another embodiment, taken along the line I-I' of FIG. 2;

FIG. 28 is a cross-sectional view of the display device according to still another embodiment, taken along the line I-I' of FIG. 2;

FIG. 29 is a cross-sectional view of the display device according to still another embodiment, taken along the line I-I' of FIG. 2;

FIG. 30 is a cross-sectional view of the display device according to still another embodiment, taken along the line I-I' of FIG. 2;

FIG. 31 is a cross-sectional view of the display device according to still another embodiment, taken along the line I-I' of FIG. 2;

FIG. 32 is a cross-sectional view of the display device according to still another embodiment, taken along the line I-I' of FIG. 2;

FIG. 33 is a cross-sectional view of the display device according to still another embodiment, taken along the line I-I' of FIG. 2;

FIG. 34 is a cross-sectional view of the display device according to still another embodiment, taken along the line I-I' of FIG. 2;

FIG. 35 is a cross-sectional view of the display device according to still another embodiment, taken along the line I-I' of FIG. 2;

FIG. 36 is a cross-sectional view of the display device according to still another embodiment, taken along the line I-I' of FIG. 2;

FIG. 37 is a block diagram of an electronic device according to one or more embodiments; and

FIGS. 38, 39, and 40 are schematic diagrams illustrating electronic devices according to various embodiments.

### DETAILED DESCRIPTION

The present disclosure will now be described more fully hereinafter with reference to the accompanying drawings, in which embodiments of the present disclosure are shown. the present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It will also be understood that when a layer is referred to as being "on" another layer or substrate, it can be directly on the other layer or substrate, or intervening layers may also be present. The same reference numbers indicate the same components throughout the specification. In the attached figures, the thickness of layers and regions is exaggerated for clarity.

Although the terms "first", "second", etc. may be used herein to describe various elements, these elements, should not be limited by these terms. These terms may be used to distinguish one element from another element. Thus, a first element discussed below may be termed a second element without departing from teachings of one or more embodiments. The description of an element as a "first" element may not require or imply the presence of a second element or other elements. The terms "first", "second", etc. may also be used herein to differentiate different categories or sets of elements. For conciseness, the terms "first", "second", etc. may represent "first-category (or first-set)", "second-category (or second-set)", etc., respectively.

Further, the phrase "in a plan view" means when an object portion is viewed from above, and the phrase "in a schematic cross-sectional view" means when a schematic cross-section taken by vertically cutting an object portion is viewed from the side. The terms "overlap" or "overlapped" mean that a first object may be above or below or to a side of a second object, and vice versa. Additionally, the term "overlap" may include layer, stack, face or facing, extending over, covering, or partly covering or any other suitable term as would be appreciated and understood by those of ordinary skill in the art. The expression "not overlap" may include meaning such as "apart from" or "set aside from" or "offset from" and any other suitable equivalents as would be appreciated and understood by those of ordinary skill in the art. The terms "face" and "facing" may mean that a first object may directly or indirectly oppose a second object. In a case in which a third object intervenes between a first and second object, the first and second objects may be understood as being indirectly opposed to one another, although still facing each other.

The spatially relative terms "below," "beneath," "lower," "above," "upper," and/or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned "below" or "beneath" another device may be placed "above" another device. Accordingly, the illustrative term "below" may include both the lower and upper positions. The device may also be oriented in other directions and thus the spatially relative terms may be interpreted differently depending on the orientations.

When an element is referred to as being "connected" or "coupled" to another element, the element may be "directly connected" or "directly coupled" to another element, or "electrically connected" or "electrically coupled" to another element with one or more intervening elements interposed therebetween. It will be further understood that when the terms "comprises," "comprising," "has," "have," "having," "includes" and/or "including" are used, they may specify the presence of stated features, integers, steps, operations, elements and/or components, but do not preclude the presence or addition of other features, integers, steps, operations, elements, components, and/or any combination thereof.

The terms "about" or "approximately" as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, "about" may mean within one or more standard deviations, or within ± 30%, 20%, 10%, 5% of the stated value.

In the specification and the claims, the term "and/or" is intended to include any combination of the terms "and" and "or" for the purpose of its meaning and interpretation. For example, "A and/or B" may be understood to mean "A, B, or A and B." The terms "and" and "or" may be used in the conjunctive or disjunctive sense and may be understood to be equivalent to "and/or." In the specification and the claims, the phrase "at least one of" is intended to include the meaning of "at least one selected from the group of" for the purpose of its meaning and interpretation. For example, "at least one of A and B" may be understood to mean "A, B, or A and B."

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Features of various embodiments of the present disclosure may be combined partially or totally. As will be clearly appreciated by those skilled in the art, technically various interactions and operations are possible. Various embodiments can be practiced individually or in combination.

Hereinafter, embodiments will be described with reference to the accompanying drawings.

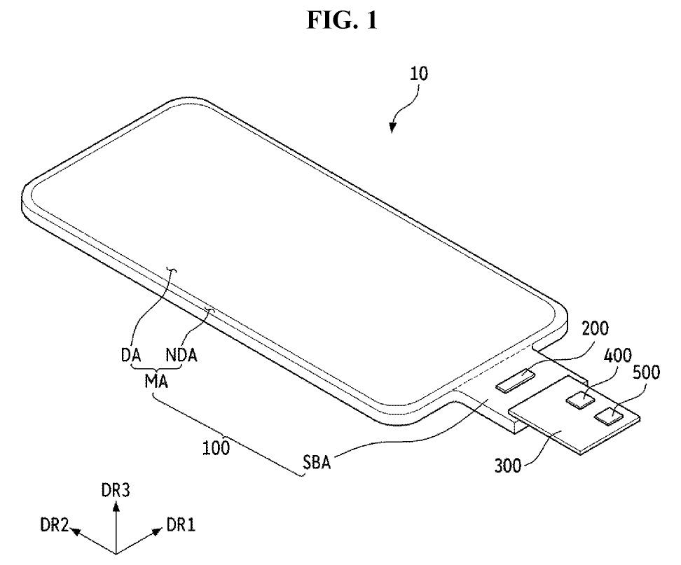

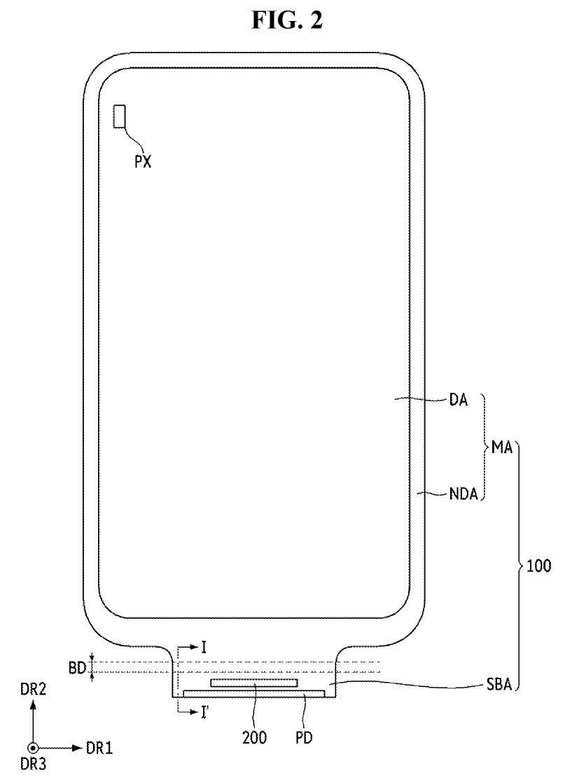

FIG. 1 is a perspective view showing a display device according to one or more embodiments, and FIG. 2 is a plan view of the display panel of FIG. 1.

Referring to FIGS. 1 and 2, the display device 10 may be applied to portable electronic devices such as a mobile phone, a smartphone, a tablet personal computer, a mobile communication terminal, an electronic organizer, an electronic book, a portable multimedia player (PMP), a navigation system, an ultra-mobile PC (UMPC), and/or the like. For example, the display device 10 may be applied as a display unit of a television, a laptop, a monitor, a billboard, or an Internet-of-Things (IoT) device. For another example, the display device 10 may be applied to wearable devices such as a smart watch, a watch phone, a glasses type display, and/or a head mounted display (HMD).

The display device 10 may have a planar shape similar to a quadrilateral shape. For example, the display device 10 may have a planar shape similar to a quadrilateral shape having a short side in a first direction DR1 and a long side in a second direction DR2. A corner where the short side in the first direction DR1 and the long side in the second direction DR2 meet may be right-angled or rounded with a suitable or selected curvature (e.g., a predetermined curvature). The planar shape of the display device 10 is not limited to a quadrilateral shape, and may be formed in a shape similar to another polygonal shape, a circular shape, or elliptical shape.

The display device 10 may include a display panel 100, a display driver 200, a circuit board 300, a touch driver 400, and a power supply unit 500.

The display panel 100 may include a main region MA and a sub-region SBA.

The main region MA may include a display area DA including pixels for displaying an image and a non-display area NDA located around the display area DA along an edge or a periphery of the display area DA. The display area DA may emit light from a plurality of emission areas or a plurality of opening areas. For example, the display panel 100 may include a pixel circuit including switching elements, a pixel defining film defining an emission area or an opening area, and a self-light emitting element.

For example, the self-light emitting element may include at least one of an organic light emitting diode (LED) including an organic light emitting layer, a quantum dot LED including a quantum dot light emitting layer, an inorganic LED including an inorganic semiconductor, or a micro LED, but is not limited thereto.

The non-display area NDA may be an area outside the display area DA. The non-display area NDA may be defined as an edge area of the main region MA of the display panel 100. The non-display area NDA may include a gate driver that supplies gate signals to the gate lines, and fan-out lines that connect the display driver 200 to the display area DA.

The sub-region SBA may extend from one side of the main region MA. The sub-region SBA may include a flexible material which can be bent, folded, and/or rolled. For example, when the sub-region SBA is bent, the sub-region SBA may overlap the main region MA in a thickness direction (e.g., a third direction DR3). The sub-region SBA may include the display driver 200 and a pad portion connected to the circuit board 300. Optionally, the sub-region SBA may be omitted, and the display driver 200 and the pad portion may be located in the non-display area NDA.

The display driver 200 may output signals and voltages for driving the display panel 100. The display driver 200 may supply data voltages to data lines. The display driver 200 may supply a power voltage to the power line, and may supply a gate control signal to the gate driver. The display driver 200 may be formed as an integrated circuit (IC) and mounted on the display panel 100 by a chip on glass (COG) method, a chip on plastic (COP) method, or an ultrasonic bonding method. For example, the display driver 200 may be located in the sub-region SBA, and may overlap the main region MA in the thickness direction (e.g., the third direction DR3) by bending of the sub-region SBA. For another example, the display driver 200 may be mounted on the circuit board 300.

The circuit board 300 may be attached to the pad portion of the display panel 100 by using an anisotropic conductive film (ACF). Lead lines of the circuit board 300 may be electrically connected to the pad portion of the display panel 100. The circuit board 300 may be a flexible printed circuit board (FPCB), a printed circuit board (PCB), or a flexible film such as a chip on film.

The touch driver 400 may be mounted on the circuit board 300. The touch driver 400 may be electrically connected to a touch sensing unit of the display panel 100. The touch driver 400 may supply a touch driving signal to a plurality of touch electrodes of the touch sensing unit and may sense an amount of change in capacitance between the plurality of touch electrodes. For example, the touch driving signal may be a pulse signal having a selected frequency. The touch driver 400 may calculate whether an input is made and input coordinates based on an amount of change in capacitance between the plurality of touch electrodes. The touch driver 400 may be formed as an integrated circuit (IC).

The power supply unit 500 may be located on the circuit board 300 to supply a power voltage to the display driver 200 and the display panel 100. The power supply unit 500 may generate a driving voltage to supply it to a driving voltage line VDL, generate an initialization voltage (e.g., a first initialization voltage and a second initialization voltage) to supply it to an initialization voltage line (e.g., a first initialization voltage line VIL1 and a second initialization voltage line VIL2), and generate a common voltage to supply it to a common electrode which is common to light emitting elements of the plurality of pixels. For example, the driving voltage may be a high potential voltage for driving the light emitting element, and the common voltage may be a low potential voltage for driving the light emitting element.

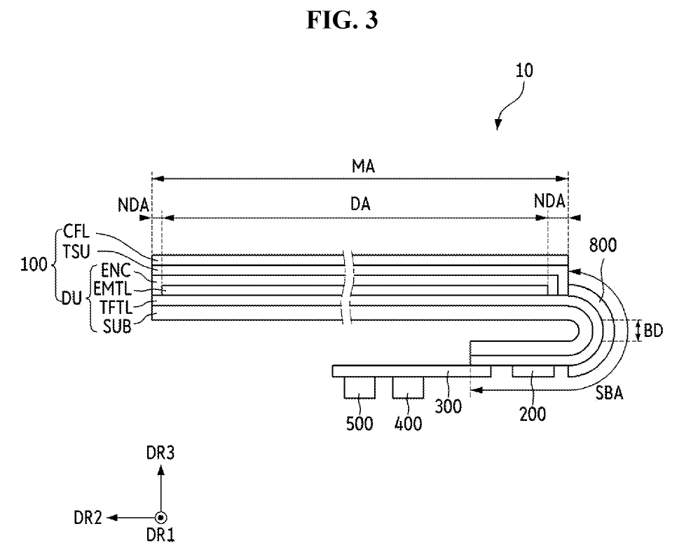

FIG. 3 is a cross-sectional view illustrating a display device according to one or more embodiments.

Referring to FIG. 3, the display panel 100 may include a display unit DU, a touch sensing unit TSU, and a color filter layer CFL. The display unit DU may include a substrate SUB, a thin film transistor layer TFTL, a light emitting element layer EMTL, and an encapsulation layer ENC.

The substrate SUB may be a base substrate or a base member. The substrate SUB may be a flexible substrate that can be bent, folded, and/or rolled. For example, the substrate SUB may include a polymer resin such as polyimide (PI), but is not limited thereto. For another example, the substrate SUB may include a glass material or a metal material.

The thin film transistor layer TFTL may be located on the substrate SUB. The thin film transistor layer TFTL may include a plurality of thin film transistors constituting a pixel circuit of pixels. The thin film transistor layer TFTL may further include gate lines, data lines, power lines, gate control lines, fan-out lines that connect the display driver 200 to the data lines, and lead lines that connect the display driver 200 to the pad portion. Each of the thin film transistors may include a semiconductor region, a source electrode, a drain electrode, and a gate electrode. For example, when the gate driver is formed on one side of the non-display area NDA of the display panel 100, the gate driver may include thin film transistors (TFTs).

The thin film transistor layer TFTL may be located in the display area DA, the non-display area NDA, and the sub-region SBA. Thin film transistors, gate lines, data lines, and power lines of each of the pixels of the thin film transistor layer TFTL may be located in the display area DA. Gate control lines and fan-out lines of the thin film transistor layer TFTL may be located in the non-display area NDA. The lead lines of the thin film transistor layer TFTL may be located in the sub-region SBA.

The light emitting element layer EMTL may be located on the thin film transistor layer TFTL. The light emitting element layer EMTL may include a plurality of light emitting elements in which a pixel electrode, a light emitting layer, and a common electrode are sequentially stacked to emit light, and a pixel defining film defining pixels. The plurality of light emitting elements of the light emitting element layer EMTL may be located in the display area DA.

For example, the light emitting layer may be an organic light emitting layer including an organic material. The light emitting layer may include a hole transporting layer, an organic light emitting layer, and an electron transporting layer. When the pixel electrode receives a selected voltage through the thin film transistor of the thin film transistor layer TFTL and the common electrode receives the cathode voltage, holes and electrons may be transferred to the organic light emitting layer through the hole transporting layer and the electron transporting layer, respectively, and may be combined with each other to emit light in the organic light emitting layer. For example, the pixel electrode may be an anode electrode, and the common electrode may be a cathode electrode, but the present disclosure is not limited thereto.

For another example, the plurality of light emitting elements may include a quantum dot light emitting diode including a quantum dot light emitting layer, an inorganic light emitting diode including an inorganic semiconductor, or a micro light emitting diode.

The encapsulation layer ENC may cover the top surface and the side surface of the light emitting element layer EMTL, and may protect the light emitting element layer EMTL. The encapsulation layer ENC may include at least one inorganic layer and at least one organic layer for encapsulating the light emitting element layer EMTL.

The touch sensing unit TSU may be located on the encapsulation layer ENC. The touch sensing unit TSU may include a plurality of touch electrodes for sensing a user's touch in a capacitive manner, and touch lines connecting the plurality of touch electrodes to the touch driver 400. For example, the touch sensing unit TSU may sense the user's touch by using a mutual capacitance method or a self-capacitance method.

For another example, the touch sensing unit TSU may be located on a separate substrate located on the display unit DU. In this case, the substrate supporting the touch sensing unit TSU may be a base member that encapsulates the display unit DU.

The plurality of touch electrodes of the touch sensing unit TSU may be located in a touch sensor area overlapping the display area DA. The touch lines of the touch sensing unit TSU may be located in a touch peripheral area that overlaps the non-display area NDA.

The color filter layer CFL may be located on the touch sensing unit TSU. The color filter layer CFL may include a plurality of color filters respectively corresponding to the plurality of emission areas. Each of the color filters may selectively transmit light of a specific wavelength and may block or absorb light of a different wavelength. The color filter layer CFL may absorb a part of light coming from the outside of the display device 10 to reduce reflected light due to external light. Accordingly, the color filter layer CFL may prevent color distortion caused by reflection of the external light.

Because the color filter layer CFL is directly located on the touch sensing unit TSU, the display device 10 may not require a separate substrate for the color filter layer CFL. Therefore, the thickness of the display device 10 may be relatively reduced.

The sub-region SBA of the display panel 100 may extend from one side of the main region MA. The sub-region SBA may include a flexible material that can be bent, folded, and/or rolled. For example, when the sub-region SBA is bent, the sub-region SBA may overlap the main region MA in the thickness direction (e.g., the third direction DR3). The sub-region SBA may include the display driver 200 and a pad portion PD electrically connected to the circuit board 300.

As illustrated in FIGS. 2 and 3, at least a part of the sub-region SBA may be bent. For example, the sub-region may include a bending area BD where the display panel 100 is bent. The bending area BD may be located between the display area DA and the pad portion PD (or display driver 200).

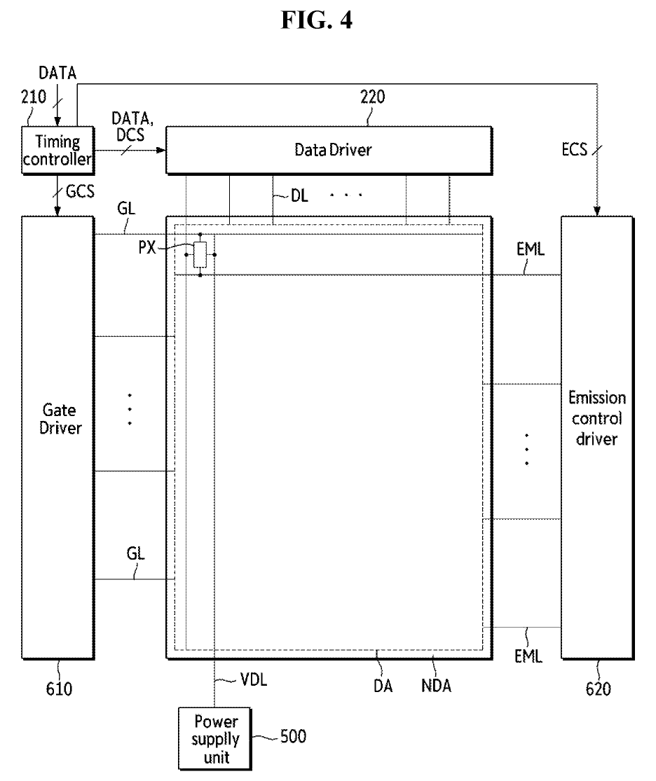

FIG. 4 is a block diagram illustrating the display panel 100 and the display driver 200 according to one or more embodiments.

Referring to FIG. 4, the display panel 100 may include the display area DA and the non-display area NDA.

The display area DA may include a plurality of pixels PX, and a plurality of driving voltage lines VDL, a plurality of gate lines GL, a plurality of emission control lines EML, and a plurality of data lines DL that are connected to the plurality of pixels PX.

Each of the plurality of pixels PX may be connected to the gate line GL, the data line DL, the emission control line EML, the driving voltage line VDL, and a common voltage line. Each of the pixels PX may include at least one transistor, a light emitting element, and a capacitor.

The gate lines GL may sequentially supply gate signals to the plurality of pixels PX.

The emission control lines EML may sequentially supply an emission control signal to the plurality of pixels PX.

The data lines DL may supply data voltages to the plurality of pixels PX. The data voltage may determine the luminance of each of the pixels PX.

The driving voltage lines VDL may supply a driving voltage to the plurality of pixels PX. The first driving voltage may be a high potential voltage for driving the light emitting elements of the pixels PX.

The non-display area NDA may be around (e.g., surround) the display area DA. A gate driver 610 and an emission control driver 620 may be located in the non-display area NDA.

The display driver 200 may include a timing controller 210 and a data driver 220.

The timing controller 210 may receive digital video data DATA and timing signals from the circuit board 300. The timing controller 210 may generate, based on the timing signals, a data control signal DCS to control the operation timing of the data driver 220, the gate control signal GCS to control the operation timing of the gate driver 610, and the emission control signal ECS to control the operation timing of the emission control driver 620. Further, the timing controller 210 may supply the digital video data DATA and the data control signal DCS to the data driver 220.

The data driver 220 may convert the digital video data DATA into analog data voltages and supply them to the data lines DL through the fan-out lines. The gate signals of the gate driver 610 may select the pixels PX to which the data voltage is supplied, and the selected pixels PX may receive the data voltage through the data lines DL.

The power supply unit 500 may be located on the circuit board 300 to supply a power voltage to the display driver 200 and the display panel 100. The power supply unit 500 may generate a driving voltage to supply it to a driving voltage line VDL, and may generate a common voltage to supply it to a common electrode that is common to the light emitting elements of the plurality of pixels PX. Here, the common voltage may be supplied to the light emitting elements of the pixels through the common voltage line.

The gate driver 610 may be located at one external side of the display area DA or at one side of the non-display area NDA. The emission control driver 620 may be located at the other external side of the display area DA or at the other side of the non-display area NDA. However, the present disclosure is not limited thereto. As another example, the gate driver 610 and the emission control driver 620 may be located at any one of one side and the other side of the non-display area NDA.

The gate driver 610 may include a plurality of transistors for generating gate signals based on the gate control signal GCS. The emission control driver 620 may include a plurality of transistors for generating emission control signals based on the emission control signal ECS. For example, the transistors of the gate driver 610 and the transistors of the emission control driver 620 may be formed on (e.g., at) the same layer as the transistors of each of the pixels PX. The gate driver 610 may supply the gate signals to the gate lines GL, and the emission control driver 620 may supply the emission control signals to the emission control lines EML.

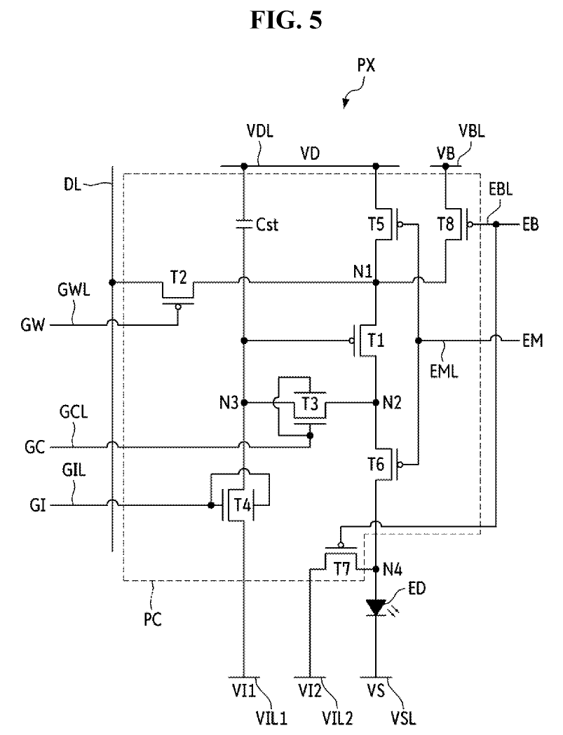

FIG. 5 is a circuit diagram of one pixel PX of a display device according to one or more embodiments. For example, FIG. 5 may be a circuit diagram for the pixel PX of FIGS. 2 or 4.

As illustrated in FIG. 5, the pixel PX may be connected to a first gate line GWL, a second gate line GCL, a third gate line GIL, a fourth gate line EBL, an emission control line EML, a data line DL, a driving voltage line VDL, a common voltage line VSL, a first initialization voltage line VIL1, a second initialization voltage line VIL2, and a bias voltage line VBL.

The pixel PX may include a pixel circuit PC and a light emitting element ED. The pixel circuit PC may include a first transistor T1, a second transistor T2, a third transistor T3, a fourth transistor T4, a fifth transistor T5, a sixth transistor T6, a seventh transistor T7, an eighth transistor T8, and a capacitor Cst.

The first transistor T1 may include a gate electrode, a source electrode, and a drain electrode. The first transistor T1 may control a source-drain current (e.g., a driving current) according to the data voltage applied to the gate electrode of the first transistor T1. The driving current flowing through the channel region of the first transistor T1 may be proportional to the square of a difference between a threshold voltage and a voltage between the source electrode and the gate electrode of the first transistor T1.

The light emitting element ED may emit light by receiving a driving current. The light emission amount or the luminance of the light emitting element ED may be proportional to the magnitude of the driving current.

The light emitting element ED may be an organic light emitting diode (OLED) including a first electrode, a second electrode, and an organic light emitting layer located between the first electrode and the second electrode. For another example, the light emitting element ED may be an inorganic light emitting element including a first electrode, a second electrode, and an inorganic semiconductor located between the first electrode and the second electrode. For still another example, the light emitting element ED may be a quantum dot light emitting element including a first electrode, a second electrode, and a quantum dot light emitting layer located between the first electrode and the second electrode. For still another example, the light emitting element ED may be a micro light emitting diode.

The first electrode of the light emitting element ED may be electrically connected to a fourth node N4. The first electrode of the light emitting element ED may be connected to the drain electrode of the sixth transistor T6 and the source electrode of the seventh transistor T7 through the fourth node N4. The second electrode of the light emitting element ED may be connected to the common voltage line VSL. The second electrode of the light emitting element ED may receive a common voltage VS (e.g., low potential voltage) from the common voltage line VSL.

The second transistor T2 may be turned on by a first gate signal GW of the first gate line GWL to electrically connect the data line DL with a first node N1 that is the source electrode of the first transistor T1. The second transistor T2 may be turned on according to the first gate signal to supply the data voltage to the first node N1. The gate electrode of the second transistor T2 may be electrically connected to the first gate line GWL, the source electrode thereof may be electrically connected to the data line DL, and the drain electrode thereof may be electrically connected to the first node N1.

The third transistor T3 may be turned on by a second gate signal GC of the second gate line GCL to electrically connect a second node N2, which is the drain electrode of the first transistor T1, to a third node N3, which is the gate electrode of the first transistor T1. The third transistor T3 may be connected between the third node N3 and the second node N2. For example, the gate electrode of the third transistor T3 may be electrically connected to the second gate line GCL, the source electrode thereof may be electrically connected to the third node N3, and the drain electrode thereof may be electrically connected to the second node. The third transistor T3 may be turned on by a second gate signal of the second gate line GCL to electrically connect the second node N2, which is the drain electrode of the first transistor T1, to the third node N3, which is the gate electrode of the first transistor T1. For example, when the third transistor T3 is turned on, the first transistor may be diode-connected. The third transistor T3 may be a double gate transistor having two gate electrodes (e.g., a gate electrode and a counter gate electrode). The gate electrode and the counter gate electrode may be located to face each other in different layers.

The fourth transistor T4 may be turned on by a third gate signal GI of the third gate line GIL to electrically connect the third node N3, which is the gate electrode of the first transistor T1, to the first initialization voltage line VIL1. The fourth transistor T4 may be connected in series between the third node N3 and the first initialization voltage line VIL1. For example, the gate electrode of the fourth transistor T4 may be electrically connected to the third gate line GIL, the source electrode thereof may be electrically connected to the third node N3, and the drain electrode thereof may be electrically connected to the first initialization voltage line VIL1. The fourth transistor T4 may be a double gate transistor. The first initialization voltage line VIL1 may transmit a first initialization voltage VI1.

The fifth transistor T5 may be turned on by an emission control signal EM of the emission control line EML to electrically connect the driving voltage line VDL with the first node N1 that is the source electrode of the first transistor T1. The gate electrode of the fifth transistor T5 may be electrically connected to the emission control line EML, the source electrode thereof may be electrically connected to the driving voltage line VDL, and the drain electrode thereof may be electrically connected to the first node N1.

The sixth transistor T6 may be turned on by the emission control signal EM of the emission control line EML to electrically connect the second node N2 that is the drain electrode of the first transistor T1 with the fourth node N4 that is the first electrode of the light emitting element ED. The gate electrode of the sixth transistor T6 may be electrically connected to the emission control line EML, the source electrode thereof may be electrically connected to the second node N2, and the drain electrode thereof may be electrically connected to the fourth node N4.

When all of the fifth transistor T5, the first transistor T1, and the sixth transistor T6 are turned on, the driving current may be supplied to the light emitting element ED.

The seventh transistor T7 may be turned on by a fourth gate signal EB of the fourth gate line EBL to electrically connect the fourth node N4 that is the first electrode of the light emitting element ED with the second initialization voltage line VIL2. By turning on the seventh transistor T7 based on the fourth gate signal, the first electrode of the light emitting element ED may be discharged to a second initialization voltage VI2. The gate electrode of the seventh transistor T7 may be electrically connected to the fourth gate line EBL, the source electrode thereof may be electrically connected to the fourth node N4, and the drain electrode thereof may be electrically connected to the second initialization voltage line VIL2. The second initialization voltage line VIL2 may transmit a second initialization voltage VI2.

The eighth transistor T8 may be turned on by the fourth gate signal EB of the fourth gate line EBL to electrically connect the bias voltage line VBL with the first node N1 that is the source electrode of the first transistor T1. The eighth transistor T8 may be turned on according to the fourth gate signal to supply a bias voltage VB to the first node N1. The eighth transistor T8 may improve hysteresis of the first transistor T1 by supplying the bias voltage VB to the source electrode of the first transistor T1. The gate electrode of the eighth transistor T8 may be electrically connected to the fourth gate line EBL, the source electrode thereof may be electrically connected to the bias voltage line VBL, and the drain electrode thereof may be electrically connected to the first node N1.

Each of the first transistor T1, the second transistor T2, the fifth transistor T5, the sixth transistor T6, the seventh transistor T7, and the eighth transistor T8 may include a silicon-based active layer. For example, each of the first transistor T1, the second transistor T2, the fifth transistor T5, the sixth transistor T6, the seventh transistor T7, and the eighth transistor T8 may be a p-type transistor including an active layer containing low temperature polycrystalline silicon (LTPS). The active layer containing low temperature polycrystalline silicon may have high electron mobility and excellent turn-on characteristics. Accordingly, in the display panel 100, because the transistors having excellent turn-on characteristics are included, it is possible to stably and efficiently drive the plurality of pixels PX. Each of the first transistor T1, the second transistor T2, the fifth transistor T5, the sixth transistor T6, the seventh transistor T7, and the eighth transistor T8 may output a current flowing into the source electrode to the drain electrode based on a gate low voltage applied to the gate electrode.

The third transistor T3 and the fourth transistor T4 may be n-type transistors including an oxide-based active layer. The transistor including the oxide-based active layer may have a coplanar structure in which a gate electrode is located thereon. The transistor including the oxide-based active layer may output a current flowing into the drain electrode to the source electrode based on a gate high voltage applied to the gate electrode.

The capacitor Cst may be electrically connected between the third node N3 that is the gate electrode of the first transistor T1 and the driving voltage line VDL. For example, the first electrode of the capacitor Cst may be electrically connected to the third node N3, and the second electrode of the capacitor Cst may be electrically connected to the driving voltage line VDL, so that a potential difference between the driving voltage line VDL and the gate electrode of the first transistor T1 may be maintained.

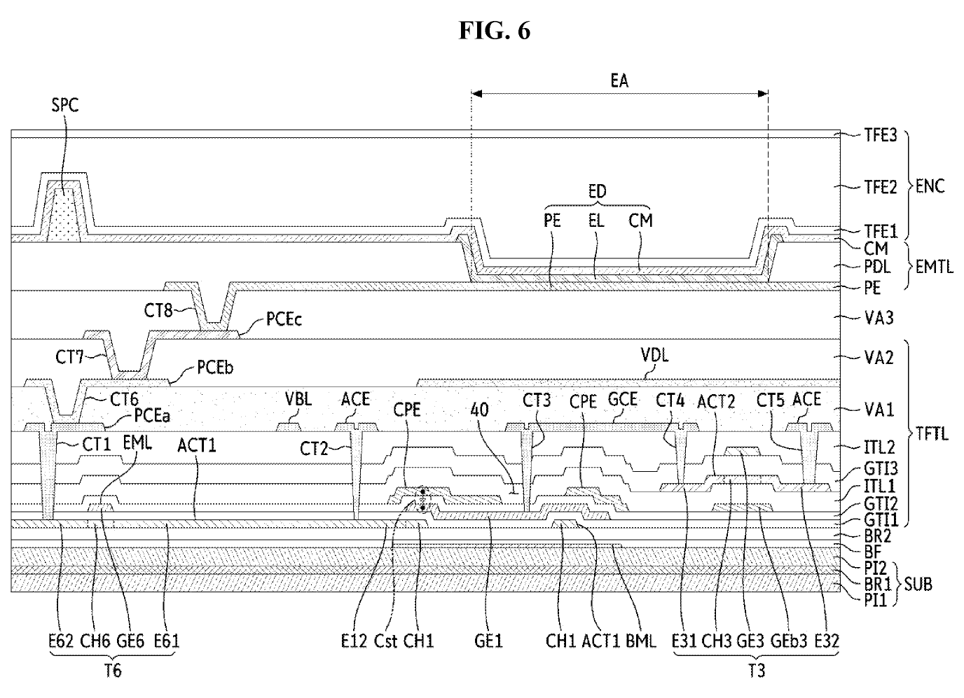

FIG. 6 is a cross-sectional view of a display device according to one or more embodiments.

As illustrated in FIG. 6, the display panel 100 may include the substrate SUB, a buffer layer, a barrier layer, the thin film transistor layer TFTL, a light emitting element layer EMTL, and the encapsulation layer ENC. The buffer layer, the barrier layer, the thin film transistor layer TFTL, the light emitting element layer EMTL, and the encapsulation layer ENC may be sequentially located on the substrate SUB along the third direction DR3.

The substrate SUB may be a rigid substrate or a flexible substrate that can be bent, folded, and/or rolled. The substrate SUB may include an insulating material such as glass, quartz, and/or a polymer resin. Examples of a polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (TAC), cellulose acetate propionate (CAP), and/or a combination thereof. Alternatively, the substrate SUB may include a metal material.

As illustrated in FIG. 6, the substrate may include a first base layer PI1, a first barrier layer BR1, and a second base layer PI2 sequentially located along the thickness direction (for example, the third direction DR3) of the substrate SUB.

The first base layer PI1 may be an insulating layer containing an organic material. The first base layer PI1 may include flexible plastic. For example, the first base layer may include polyimide (PI), polyethylene naphthalate (PEN), polyethylene terephthalate (PET), polyarylate, polycarbonate (PC), polyetherimide (PEI), and/or polyethersulfone (PES).

The first barrier layer BR1 may be located on the first base layer PI1. For example, the first barrier layer BR1 may be located between the first base layer PI1 and the second base layer PI2. The first barrier layer BR1 may include an inorganic material.

The second base layer PI2 may be located on the first barrier layer BR1. The second base layer PI2 may include the same material as the first base layer PI1 described above.

A first pattern layer may be located on the substrate SUB. For example, a light blocking layer BML may be located on the second base layer PI2 of the substrate SUB. The light blocking layer BML may be located on the second base layer to cover an overlapping region (e.g., the first channel region CH1) between the first gate electrode GE1 and the first active layer ACT1. In other words, the light blocking layer BML may be located on the second base layer PI2 to overlap the channel region CH1 of the first transistor T1, which is a driving transistor.

The light blocking layer BML may include, for example, a metallic material such as chromium (Cr) and/or molybdenum (Mo), black ink, black dye, and/or the like. When the light blocking layer BML includes a metallic material, the light blocking layer BML may be supplied with a constant power source. In this way, the light blocking layer BML is not electrically floating, and the transistor (e.g., the first transistor T1) on the light blocking layer BML may have its electrical characteristics stabilized.

A buffer layer BF may be located on the light blocking layer BML and on the second base layer PI2. The buffer layer BF may be a layer for protecting the transistors T1 to T8 of the thin film transistor layer TFTL and a light emitting layer EL of the light emitting element layer EMTL from moisture permeating through the substrate SUB that is susceptible to moisture permeation.

A second barrier layer BR2 may be located on the buffer layer BF. The second barrier layer BR2 may be a layer for protecting the transistors T1 to T8 of the thin film transistor layer TFTL and the light emitting layer EL of the light emitting element layer EMTL from moisture permeating through the substrate SUB that is susceptible to moisture permeation.

A second pattern layer may be located on the second barrier layer BR2. For example, the first active layer ACT1 may be located on the second barrier layer BR2. As shown in FIG. 6, the first active layer ACT1 may include the first channel region CH1 of the first transistor T1, the second electrode E12 of the first transistor T1, the first channel region CH1 of the first transistor T1, the first electrode E61 of the sixth transistor T6, the second electrode E62 of the sixth transistor T6, and the sixth channel region CH6 of the sixth transistor T6.

The first active layer ACT1 may be an active layer containing low temperature polycrystalline silicon (LTPS).

A first gate insulating layer GTI1 may be located on the second pattern layer and on the second barrier layer BR2. For example, as shown in FIG. 6, the first gate insulating layer GTI1 may be located on the first active layer ACT1.

The first gate insulating layer GTI1 may include at least one of tetraethylorthosilicate (TEOS), silicon nitride (SiNx), or silicon oxide (SiO₂). For example, the first gate insulating layer GTI1 may have a double-film structure in which a silicon nitride film having a thickness of 40 nm and a tetraethylorthosilicate film having a thickness of 80 nm are sequentially stacked.

A third pattern layer may be located on the first gate insulating layer GTI1. For example, the second gate electrode GE2, the first gate electrode GE1, the eighth gate electrode GE8, the emission control line EML, the fifth gate electrode GE5, and the sixth gate electrode GE6 may be located on the first gate insulating layer GTI1.

FIG. 6 illustrates an example in which the first gate electrode GE1, the sixth gate electrode GE6, and the emission control line EML are located on the first gate insulating layer GTI1. The first gate electrode GE1 may be located on the first gate insulating layer GTI1 to overlap the first channel region CH1 of the first active layer ACT1. The sixth gate electrode GE6 of the emission control line EML may be located on the first gate insulating layer GTI1 to overlap the sixth channel region CH6 of the first active layer ACT1.

The third pattern layer may include at least one of molybdenum (Mo), copper (Cu), aluminum, or titanium (Ti), and may be formed as a single layer or multiple layers. For example, the first gate electrode GE1 may be formed as a triple film including a titanium film, an aluminum film, and a titanium film located sequentially on the first gate insulating layer GTI1 along the third direction DR3.

A second gate insulating layer GTI2 may be located on the third pattern layer and on the first gate insulating layer GTI1. For example, as shown in FIG. 6, the second gate insulating layer GTI2 may be located on the first gate electrode GE1, the sixth gate electrode GE6, and the emission control line EML.

The second gate insulating layer GTI2 may include the same material and structure as the first gate insulating layer GTI1 described above.

A fourth pattern layer may be located on the second gate insulating layer GTI2. For example, the fourth counter gate electrode GEb4, the third counter gate electrode GEb3, and the capacitor electrode CPE may be located on the second gate insulating layer GTI2. FIG. 6 illustrates an example in which the capacitor electrode CPE and the third counter gate electrode GEb3 are located on the second gate insulating layer GTI2. The capacitor electrode CPE may be located on the second gate insulating layer GTI2 to overlap the first gate electrode GE1. The capacitor Cst may be formed between the capacitor electrode CPE and the first gate electrode GE1.

The fourth pattern layer may have the same material or structure as the third pattern layer described above.

A first interlayer insulating layer ITL1 may be located on the fourth pattern layer and on the second gate insulating layer GTI2. For example, as shown in FIG. 6, the first interlayer insulating layer ITL1 may be located on the capacitor electrode CPE and the third counter gate electrode GEb3.

The first interlayer insulating layer ITL1 may include an inorganic layer, for example, a silicon nitride layer, a silicon oxynitride layer, a silicon oxide layer, a titanium oxide layer, and/or an aluminum oxide layer. In some embodiments, the first interlayer insulating layer ITL1 may include a plurality of inorganic layers.

A fifth pattern layer may be located on the first interlayer insulating layer ITL1. For example, the second active layer ACT2 may be located on the first interlayer insulating layer ITL1. As shown in FIG. 6, the second active layer ACT2 may be located on the first interlayer insulating layer ITL1 to overlap the third counter gate electrode GEb3. The second active layer ACT2 may include the first electrode E31 of the third transistor T3, the second electrode E32 of the third transistor T3, and the third channel region CH3 of the third transistor T3. The third channel region CH3 of the second active layer ACT2 may overlap the third counter gate electrode GEb3.

The second active layer ACT2 may be an oxide-based active layer. For example, the second active layer ACT2 may be an oxide semiconductor containing indium-gallium-zinc oxide (IGZO) or indium-gallium-zinc-tin oxide (IGZTO).

A third gate insulating layer GTI3 may be located on the fifth pattern layer and on the first interlayer insulating layer ITL1. For example, as shown in FIG. 6, the third gate insulating layer GTI3 may be located on the second active layer ACT2.

The third gate insulating layer GTI3 may have the same material and structure as the first gate insulating layer GTI1 described above.

A sixth pattern layer may be located on the third gate insulating layer GTI3. For example, the fourth gate electrode GE4 and the third gate electrode GE3 may be located on the third gate insulating layer GTI3.

FIG. 6 illustrates an example in which the third gate electrode GE3 is located on the third gate insulating layer GTI3. The third gate electrode GE3 may be located to overlap the third channel region CH3 of the second active layer ACT2.

The sixth pattern layer may have the same material or structure as the third pattern layer described above.

A second interlayer insulating layer ITL2 may be located on the sixth pattern layer and on the third gate insulating layer GTI3. For example, as shown in FIG. 6, the second interlayer insulating layer ITL2 may be located on the third gate electrode GE3.

The second interlayer insulating layer ITL2 may have the same material and structure as the first interlayer insulating layer ITL1 described above.

A seventh pattern layer may be located on the second interlayer insulating layer ITL2. For example, the first initialization voltage line VIL1, the third gate line GIL, a data connection electrode DCE, the first gate line GWL, the second gate line GCL, a gate connection electrode GCE, an active connection electrode ACE, the bias voltage line VBL, a capacitor connection electrode CCE, a lower pixel connection electrode PCEa, the fourth gate line EBL, and the second initialization voltage line VIL2 may be located on the second interlayer insulating layer ITL2.

FIG. 6 illustrates an example in which the gate connection electrode GCE, the active connection electrode ACE, the bias voltage line VBL, and the lower pixel connection electrode PCEa are located on the second interlayer insulating layer ITL2. The lower pixel connection electrode PCEa may be connected to the second electrode E62 of the sixth transistor T6 through a first contact hole CT1 penetrating the second interlayer insulating layer ITL2, the third gate insulating layer GTI3, the first interlayer insulating layer ITL1, the second gate insulating layer GTI2, and the first gate insulating layer GTI1. The active connection electrode ACE may be connected to the second electrode E12 of the first transistor T1 and the first electrode E61 of the sixth transistor T6 through a second contact hole CT2 penetrating the second interlayer insulating layer ITL2, the third gate insulating layer GTI3, the first interlayer insulating layer ITL1, the second gate insulating layer GTI2, and the first gate insulating layer GTI1. Further, the active connection electrode ACE may be connected to the second electrode E32 of the third transistor T3 through a fifth contact hole CT5 penetrating the second interlayer insulating layer ITL2 and the third gate insulating layer GTI3. The gate connection electrode GCE may be connected to the first gate electrode GE1 through a third contact hole CT3 penetrating the second interlayer insulating layer ITL2, the third gate insulating layer GTI3, the first interlayer insulating layer ITL1, the hole 40 of the capacitor electrode CPE, and the second gate insulating layer GTI2. Further, the gate connection electrode GCE may be connected to the first electrode E31 of the third transistor T3 through a fourth contact hole CT4 penetrating the second interlayer insulating layer ITL2 and the third gate insulating layer GTI3.

The seventh pattern layer may have the same material or structure as the third pattern layer described above.

A first planarization layer VA1 may be located on the seventh pattern layer and on the second interlayer insulating layer ITL2. For example, the first planarization layer VA1 may be located on the gate connection electrode GCE, the active connection electrode ACE, the bias voltage line VBL, and the lower pixel connection electrode PCEa.

The first planarization layer VA1 may include an organic layer such as acryl resin, epoxy resin, phenolic resin, polyamide resin, polyimide resin, and/or the like.

An eighth pattern layer may be located on the first planarization layer VA1. For example, the data line DL, the driving voltage line VDL, and an intermediate pixel connection electrode PCEb may be located on the first planarization layer VA1. FIG. 6 illustrates an example in which the driving voltage line VDL and the intermediate pixel connection electrode PCEb are located on the first planarization layer VA1.

The intermediate pixel connection electrode PCEb may be connected to the lower pixel connection electrode PCEa through a sixth contact hole CT6 penetrating the first planarization layer VA1.

The eighth pattern layer may have the same material or structure as the third pattern layer described above.

A second planarization layer VA2 may be located on the eighth pattern layer and on the first planarization layer VA1. For example, the second planarization layer VA2 may be located on the driving voltage line VDL and the intermediate pixel connection electrode PCEb.

The second planarization layer VA2 may have the same material and structure as the first planarization layer VA1 described above.

A ninth pattern layer may be located on the second planarization layer VA2. For example, an upper pixel connection electrode PCEc and various wires may be located on the second planarization layer VA2. FIG. 6 illustrates an example in which the upper pixel connection electrode PCEc is located on the second planarization layer VA2.

The upper pixel connection electrode PCEc may be connected to an intermediate pixel connection electrode PCEb through a seventh contact hole CT7 penetrating the second planarization layer VA2.

The ninth pattern layer may have the same material or structure as the third pattern layer described above.

A third planarization layer VA3 may be located on the ninth pattern layer and on the second planarization layer VA2. For example, the third planarization layer VA3 may be located on the upper pixel connection electrode PCEc.

The third planarization layer VA3 may have the same material and structure as the first planarization layer VA1 described above.

A tenth pattern layer may be located on the third planarization layer VA3. For example, as shown in FIG. 6, the light emitting element layer EMTL including the tenth pattern layer may be located on the third planarization layer VA3. For example, as shown in FIG. 6, the pixel electrode PE may be located on the third planarization layer VA3, as the tenth pattern layer. The pixel electrode PE may be connected to the upper pixel connection electrode PCEc through an eighth contact hole CT8 penetrating the third planarization layer VA3.

In addition to the aforementioned tenth pattern layer, the above-described light emitting element layer EMTL may further include the light emitting element ED and the bank PDL (or pixel defining layer).

The light emitting element ED may include the pixel electrode PE, the light emitting layer EL, and the common electrode CM. An emission area EA, in which the pixel electrode PE, the light emitting layer EL, and the common electrode CM are sequentially stacked, indicates an area in which holes from the pixel electrode PE and electrons from the common electrode CM are combined with each other in the light emitting layer EL to emit light. In this case, the pixel electrode PE may be the anode electrode of the light emitting element ED, and the common electrode CM may be the cathode electrode of the light emitting element ED.

In a top emission structure that emits light toward the common electrode CM with respect to the light emitting layer EL, the pixel electrode PE may be formed as a single layer of molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and ITO, an APC alloy, or a stacked structure (ITO/APC/ITO) of APC alloy and ITO to increase the reflectivity. The APC alloy is an alloy of silver (Ag), palladium (Pd) and copper (Cu).

The bank PDL (or pixel defining layer) may serve to define the emission areas EA of the pixels PX. To this end, the bank PDL may be located to expose a part of the pixel electrode PE on the third planarization layer VA3. The bank PDL may cover the edge of the pixel electrode PE. The bank PDL may be located in the eighth contact hole CT8 penetrating the third planarization layer VA3. Accordingly, the eighth contact hole CT8 penetrating the third planarization layer VA3 may be filled with the bank PDL. The bank PDL may include an organic layer such as acryl resin, epoxy resin, phenolic resin, polyamide resin, polyimide resin, and/or the like.

As shown in FIG. 6, a spacer SPC may be located on the bank PDL. The spacer SPC may serve to support a mask during a process of manufacturing the light emitting layer EL. The spacer SPC may be formed as an organic layer such as acryl resin, epoxy resin, phenolic resin, polyamide resin, polyimide resin, and/or the like.

The light emitting layer EL may be formed on the pixel electrode PE. The light emitting layer EL may include an organic material to emit light in a desired color (e.g., a selected color or a predetermined color). For example, the light emitting layer EL may include a hole transporting layer, an organic material layer, and an electron transporting layer. The organic material layer may include a host and a dopant. The organic material layer may include a material that emits desired light (e.g., selected light), and may be formed using a phosphorescent material and/or a fluorescent material.

The aforementioned light emitting element ED may be provided for each pixel PX. For example, a first pixel may include a first light emitting element, a second pixel may include a second light emitting element, and a third pixel may include a third light emitting element. The first light emitting element, the second light emitting element, and the third light emitting element may provide light of different colors. For example, the first light emitting element may emit light of a first color, the second light emitting element may emit light of a second color, and the third light emitting element may emit light of a third color.

For example, the organic material layer of the first light emitting layer of the first emission area for emitting the light of the first color may be a phosphorescent material including a host material including carbazole biphenyl (CBP) or 1,3-bis(carbazol-9-yl)benzene (mCP), and a dopant including at least one selected from the group consisting of bis(1-phenylisoquinoline)acetylacetonate iridium (PIQIr(acac)), bis(1-phenylquinoline)acetylacetonate iridium (PQIr(acac)), tris(1-phenylquinoline)iridium (PQIr) and octaethylporphyrin platinum (PtOEP). Alternatively, the organic material layer of the first light emitting layer of the first emission area may be a fluorescent material including PBD:Eu(DBM)3(Phen) or Perylene, but the present disclosure is not limited thereto.

The organic material layer of the second light emitting layer of the second emission area for emitting the light of the second color may be a phosphorescent material including a host material including CBP or mCP, and a dopant material including fac-tris(2-phenylpyridine)iridium (Ir(ppy)₃). Alternatively, the organic material layer of the second light emitting layer of the second emission area for emitting the light of the second color may be a fluorescent material including tris(8-hydroxyquinolino)aluminum (Alq 3 ), but the present disclosure is not limited thereto.

The organic material layer of the light emitting layer of the third emission area for emitting the light of the third color may be a phosphorescent material including a host material including CBP or mCP, and a dopant material including (4,6-F2ppy)2Irpic or L2BD111, but the present disclosure is not limited thereto.

The common electrode CM may be located on the first, second, and third light emitting layers (e.g., EL). The common electrode CM may be located to cover the first, second, and third light emitting layers. The common electrode CM may be a common layer commonly located in the first to third light emitting layers. A capping layer may be formed on the common electrode CM.

In the top emission structure, the common electrode CM may include a transparent conductive material (TCO) such as ITO and/or IZO capable of transmitting light or a semi-transmissive conductive material such as magnesium (Mg), silver (Ag), and/or an alloy of magnesium (Mg) and silver (Ag). When the common electrode CM includes a semi-transmissive conductive material, the light emission efficiency can be increased due to a micro-cavity effect.

The encapsulation layer ENC may be formed on the light emitting element layer EMTL. The encapsulation layer ENC may include at least one inorganic layer TFE1 and TFE3 to prevent oxygen and/or moisture from permeating into the light emitting element layer EMTL. In addition, the encapsulation layer ENC may include at least one organic layer to protect the light emitting element layer EMTL from foreign substances such as dust. For example, the encapsulation layer ENC may include a first encapsulation inorganic layer TFE1, an encapsulation organic layer TFE2, and a second encapsulation inorganic layer TFE3.

The first encapsulation inorganic layer TFE1 may be located on the common electrode CM, the encapsulation organic layer TFE2 may be located on the first encapsulation inorganic layer TFE1, and the second encapsulation inorganic layer TFE3 may be located on the encapsulation organic layer TFE2. The first encapsulation inorganic layer TFE1 and the second encapsulation inorganic layer TFE3 may be formed as multiple films in which one or more inorganic layers of a silicon nitride layer, a silicon oxynitride layer, a silicon oxide layer, a titanium oxide layer, and an aluminum oxide layer are alternately stacked. The encapsulation organic layer TFE2 may be an organic layer such as acryl resin, epoxy resin, phenolic resin, polyamide resin, polyimide resin, and/or the like.

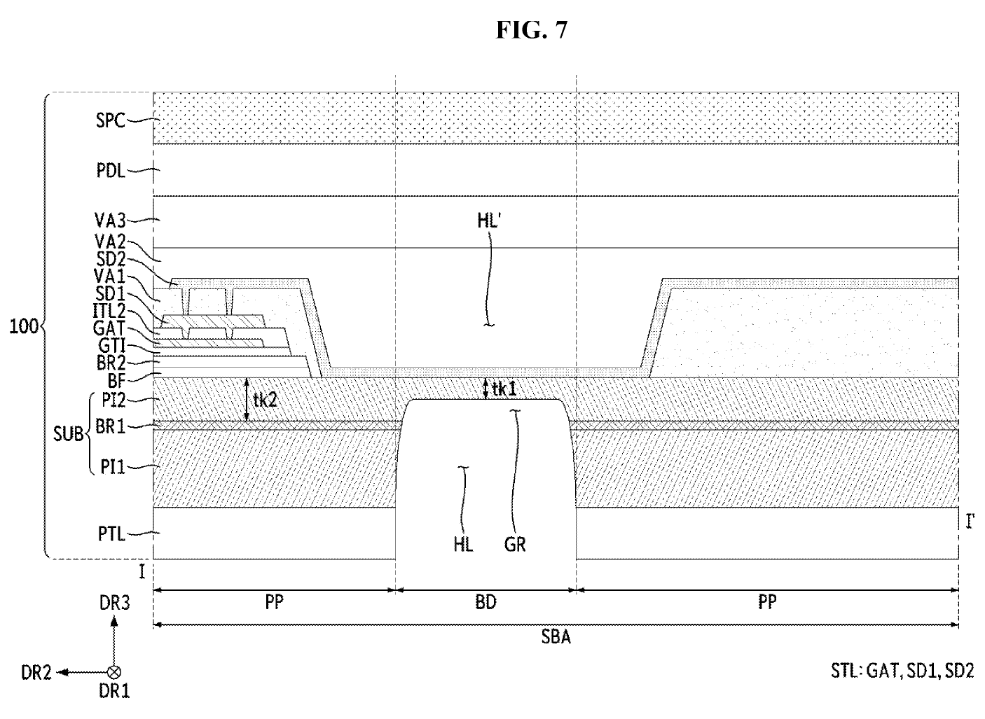

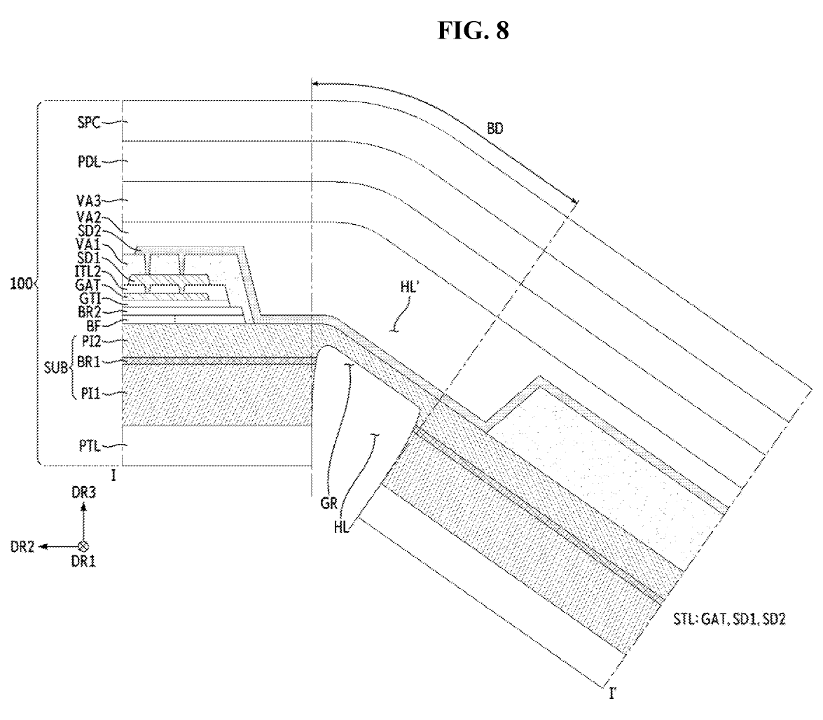

FIG. 7 is a cross-sectional view of the display device 10 according to one or more embodiments, taken along the line I-I' of FIGS. 2 and 8 is a drawing illustrating the bent state of the display device 10 of FIG. 7.

In the sub-region SBA, the buffer layer BF, the second barrier layer BR2, the gate insulating layer GTI, a gate pattern layer GAT, the second interlayer insulating layer ITL2, a first source pattern layer SD1, the first planarization layer VA1, a second source pattern layer SD2, the second planarization layer VA2, the third planarization layer VA3, the bank PDL, and the spacer SPC may be located on the substrate SUB (for example, the top surface of the substrate SUB). For example, in the sub-region SBA, the buffer layer BF may be located on the substrate SUB, the second barrier layer BR2 may be located on the buffer layer BF, the gate insulating layer GTI may be located on the second barrier layer BR2, the gate pattern layer GAT may be located on the gate insulating layer GTI, the second interlayer insulating layer ITL2 may be located on the gate pattern layer GAT, the first source pattern layer SD1 may be located on the second interlayer insulating layer ITL2, the first planarization layer VA1 may be located on the first source pattern layer SD1, the second source pattern layer SD2 may be located on the first planarization layer VA1, the second planarization layer VA2 may be located on the second source pattern layer SD2, the third planarization layer VA3 may be located on the second planarization layer VA2, the bank PDL may be located on the third planarization layer VA3, and the spacer SPC may be located on the bank PDL. Here, the buffer layer BF and the second barrier layer BR2 may not overlap the bending area BD of the sub-region SBA. For example, the buffer layer BF and the second barrier layer BR2 may not be located in the bending area BD.

The gate insulating layer GTI described above may include the first gate insulating layer GTI1, the second gate insulating layer GTI2, and the third gate insulating layer GTI3 that are described above.

The gate pattern layer GAT described above may be located on (e.g., at) the same layer as the third gate electrode GE3 described above. For example, the first gate pattern layer GAT may be included in the sixth pattern layer.

The first source pattern layer SD1 described above may be located on (e.g., at) the same layer as the lower pixel connection electrode PCEa described above. For example, the first source pattern layer SD1 may be included in the seventh pattern layer. The first source pattern layer SD1 may be connected to the gate pattern layer GAT through a contact hole penetrating the second interlayer insulating layer ITL2.

The second source pattern layer SD2 described above may be located on (e.g., at) the same layer as the intermediate pixel connection electrode PCEb described above. For example, the second source pattern layer SD2 may be included in the eighth pattern layer. The second source pattern layer SD2 may be connected to the first source pattern layer SD1 through a contact hole penetrating the first planarization layer VA1. The second source pattern layer SD2 may overlap the bending area BD of the display panel 100. In the bending area BD, the second source pattern layer SD2 may be located on the second base layer PI2 of the substrate SUB. In the bending area BD, the second source pattern layer SD2 may be in contact with (or in direct contact with) the second base layer PI2.

The gate pattern layer GAT, the first source pattern layer SD1, and the second source pattern layer SD2 that are described above may be connected to each other to form a signal transmission line STL. In other words, the signal transmission line STL may include the gate pattern layer GAT, the first source pattern layer SD1, and the second source pattern layer SD2 that are connected to each other. The signal transmission line STL may supply various signals (for example, data voltage, power voltage) from the display driver 200 to the pixels PX. In other words, among a plurality of signal transmission lines STL, any one signal transmission line STL may transmit the data voltage, and another signal transmission line STL may transmit the power voltage.

The second source pattern layer SD2, the second planarization layer VA2, the third planarization layer VA3, the bank PDL, and the spacer SPC that are described above may be located in the sub-region SBA. The second source pattern layer SD2, the second planarization layer VA2, the third planarization layer VA3, the bank PDL, and the spacer SPC may overlap the bending area BD. For example, at least a part of the second source pattern layer SD2, at least a part of the second planarization layer VA2, at least a part of the third planarization layer VA3, at least a part of the bank PDL, and at least a part of the spacer SPC may each be located in the bending area BD.

Referring to FIG. 7, a substrate protective layer PTL may be located on the bottom surface of the substrate SUB. For example, the display panel 100 may further include the substrate protective layer PTL located on the bottom surface of the substrate SUB. The substrate protective layer PTL may be located on the bottom surface of the substrate SUB so as not to overlap the bending area BD. The substrate protective layer PTL may protect the bottom surface of the substrate SUB, for example, the first base layer PI1 (for example, the bottom surface of the first base layer PI1) of the substrate SUB.

Referring to FIG. 7, the thickness of the substrate SUB may be different in the bending area BD of the display panel 100. For example, when the remaining area of the sub-region SBA excluding the bending area BD of the substrate SUB is defined as a peripheral area PP of the substrate SUB, the thickness of the substrate SUB in the bending area BD may be less than the thickness of the substrate SUB in the peripheral area PP (for example, the peripheral area PP of the sub-region SBA). Here, the thickness of the substrate SUB may be, e.g., the size of the substrate SUB in the third direction DR3.

For example, the thickness of the first base layer PI1 in the bending area BD may be less than the thickness of the first base layer PI1 in the peripheral area PP. According to one or more embodiments, the thickness of the first base layer PI1 in the bending area BD may be substantially zero “0”, and the thickness of the first base layer PI1 in the peripheral area PP may be greater than zero “0”.

Further, the thickness of the first barrier layer BR1 in the bending area BD may be less than the thickness of the first barrier layer BR1 in the peripheral area PP. According to one or more embodiments, the thickness of the first barrier layer BR1 in the bending area BD may be substantially zero “0”, and the thickness of the first barrier layer BR1 in the peripheral area PP may be greater than zero “0”.

Further, a thickness tk1 of the second base layer PI2 in the bending area BD may be less than a thickness tk2 of the second base layer PI2 in the peripheral area PP. According to one or more embodiments, the thickness tk1 of the second base layer PI2 in the bending area BD may be greater than 0, and the thickness tk2 of the second base layer PI2 in the peripheral area PP may be greater than the thickness of the second base layer PI2 in the bending area BD.

As described above, the thickness of the substrate SUB in the bending area BD may be less than the thickness of the substrate SUB in the peripheral area PP. In one or more embodiments, the substrate SUB may have a trench in the bending area BD, and the trench may include at least one of a groove GR or a hole HL. For example, in the bending area BD, the substrate SUB may include the hole HL penetrating the first base layer PI1 and the first barrier layer BR1 in the third direction DR3, and the groove GR located on the bottom surface of the second base layer PI2 to overlap the hole HL. Here, the groove GR of the second base layer PI2 may have a concave shape that is recessed in a direction (for example, the third direction DR3) from the bottom surface of the second base layer PI2 toward the top surface of the second base layer PI2.

Further, the thickness of the first planarization layer VA1 may be different in the bending area BD of the display panel 100. For example, the thickness of the first planarization layer VA1 in the bending area BD may be less than the thickness of the first planarization layer VA1 in the peripheral area PP. In one or more embodiments, the thickness of the first planarization layer VA1 in the bending area BD may be substantially zero “0”, and the thickness of the first planarization layer VA1 in the peripheral area PP may be greater than zero “0”. As one or more embodiments for this, the first planarization layer VA1 may have a trench in the bending area BD. For example, the first planarization layer VA1 may have a hole HL' in the bending area BD. The hole HL' may penetrate the first planarization layer VA1 in the third direction DR3 in the bending area BD. The hole HL' of the first planarization layer VA1 may overlap the bending area BD.

According to one or more embodiments, the substrate SUB and the first planarization layer VA1 are thinner in the bending area BD than in the peripheral area PP of the display panel 100, so that the stress in the bending area BD may be reduced when the display panel 100 is bent in the bending area BD as illustrated in FIG. 8. For example, the tensile stress and/or compressive stress applied to the second source pattern layer SD2 of the signal transmission line STL in the bending area BD may be reduced. Accordingly, when the display panel 100 is bent, damage to the signal transmission line STL (for example, the second source pattern layer SD2) may be prevented.

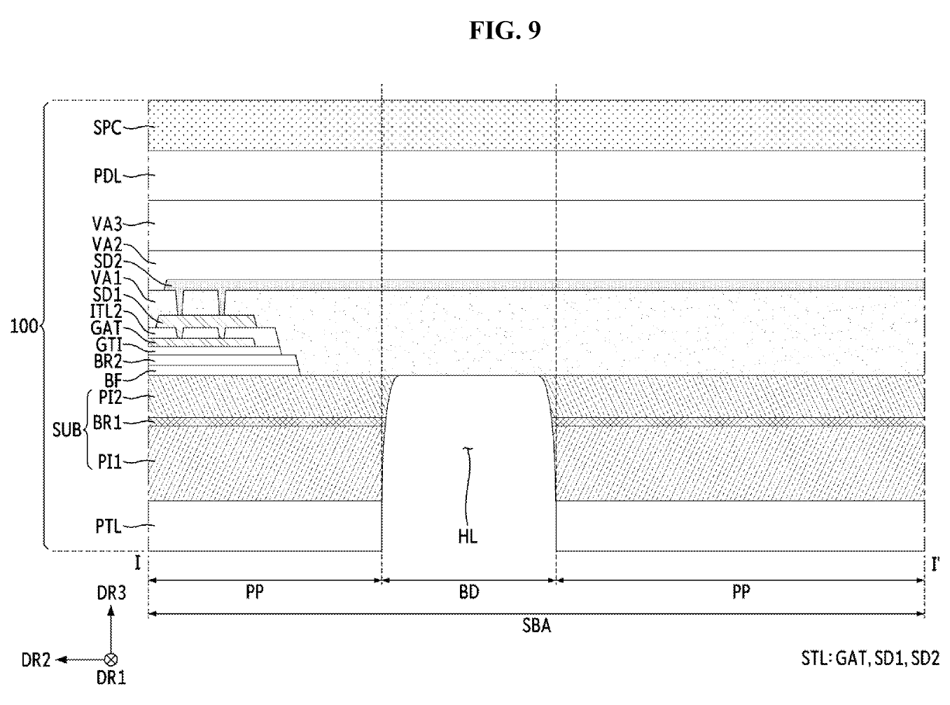

FIG. 9 is a cross-sectional view of the display device 10 according to another embodiment, taken along the line I-I' of FIG. 2.

The display device 10 of FIG. 9 differs from the display device 10 of FIG. 7 described above in terms of the first planarization layer VA1, the second source pattern layer SD2, and the substrate SUB, and the following description focuses on this difference.

Referring to FIG. 9, the first planarization layer VA1 may overlap the bending area BD of the display panel 100. For example, at least a part of the first planarization layer VA1 may be located in the bending area BD.

Referring to FIG. 9, the second source pattern layer SD2 may be located between the first planarization layer VA1 and the second planarization layer VA2 in the sub-region SBA. For example, in the bending area BD of the sub-region SBA, the second source pattern layer SD2 may be located between the first planarization layer VA1 and the second planarization layer VA2. In the bending area BD, the second source pattern layer SD2 may overlap the hole HL of the substrate SUB. For example, in the bending area BD, the second source pattern layer SD2 may be located on the first planarization layer VA1 to overlap the hole HL of the substrate SUB.

Referring to FIG. 9, the thickness of the second base layer PI2 in the bending area BD may be less than the thickness of the second base layer PI2 in the peripheral area PP. According to one or more embodiments, the thickness of the second base layer PI2 in the bending area BD may be substantially zero “0”, and the thickness of the second base layer PI2 in the peripheral area PP may be greater than zero “0”.

As described above, the thickness of the substrate SUB in the bending area BD may be less than the thickness of the substrate SUB in the peripheral area PP. According to one or more embodiments for this, the substrate SUB may have the hole HL as a trench penetrating the first base layer PI1, the first barrier layer BR1, and the second base layer PI2 in the third direction DR3 in the bending area BD. The first planarization layer VA1 may be exposed by the hole HL in the bending area BD. For example, the first planarization layer VA1 may overlap the hole HL of the substrate SUB in the bending area BD.

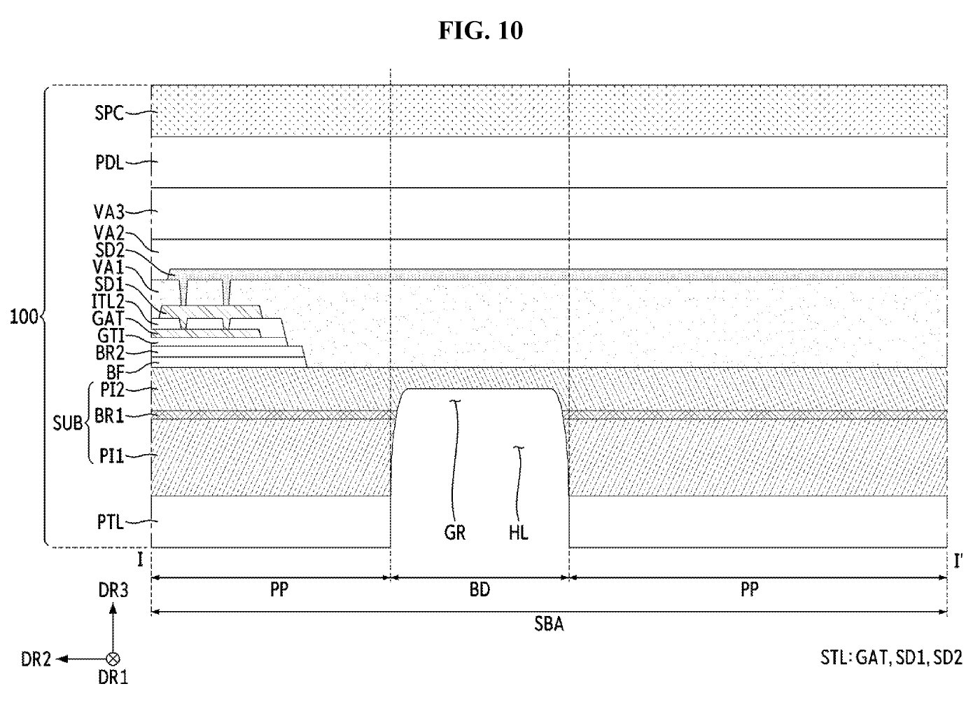

FIG. 10 is a cross-sectional view of the display device 10 according to still another embodiment, taken along the line I-I' of FIG. 2.

The display device 10 of FIG. 10 differs from the display device 10 of FIG. 9 described above in terms of the second base layer PI2, and the following description focuses on this difference.

Referring to FIG. 10, the substrate SUB may have at least one of the groove GR or the hole HL in the bending area BD. For example, since the groove GR and the hole HL of FIG. 10 are the same as the groove GR and the hole HL of FIG. 7 described above, the description of the groove GR and the hole HL of FIG. 10 refers to the description of the groove GR and the hole HL of FIG. 7 described above.

Referring to FIG. 10, the second base layer PI2 may be in contact (or in direct contact) with the first planarization layer VA1 in the bending area BD.

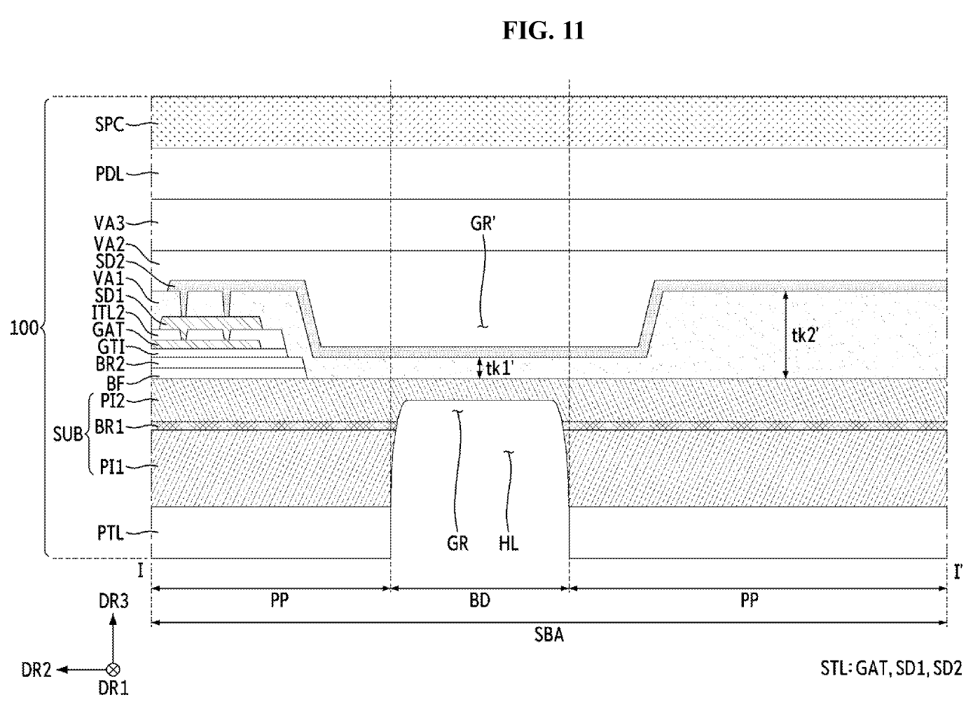

FIG. 11 is a cross-sectional view of the display device 10 according to still another embodiment, taken along the line I-I' of FIG. 2.

The display device 10 of FIG. 11 differs from the display device 10 of FIG. 10 described above in terms of the first planarization layer VA1 and the second source pattern layer SD2, and the following description focuses on this difference.

Referring to FIG. 11, a thickness tk1' of the first planarization layer VA1 in the bending area BD may be different from a thickness tk2' of the first planarization layer VA1 in the peripheral area PP. For example, the thickness tk1' of the first planarization layer VA1 in the bending area BD may be less than the thickness tk2' of the first planarization layer VA1 in the peripheral area PP. Therefore, as shown in FIG. 11, a groove GR' of the first planarization layer VA1 in the bending area BD may have a concave shape that is recessed in a direction (for example, the third reverse direction) from the top surface of the first planarization layer VA1 toward the bottom surface of the first planarization layer VA1.

Referring to FIG. 11, the height of the second source pattern layer SD2 in the bending area BD may be lower than the height of the second source pattern layer SD2 in the peripheral area PP. For example, as described above, the first planarization layer VA1 has different thicknesses in the bending area BD and the peripheral area PP, so that the second source pattern layer SD2 in the bending area BD may be located lower than the second source pattern layer SD2 in the peripheral area PP. For example, the second source pattern layer SD2 in the bending area BD may be located closer to the substrate SUB than the second source pattern layer SD2 in the peripheral area PP.

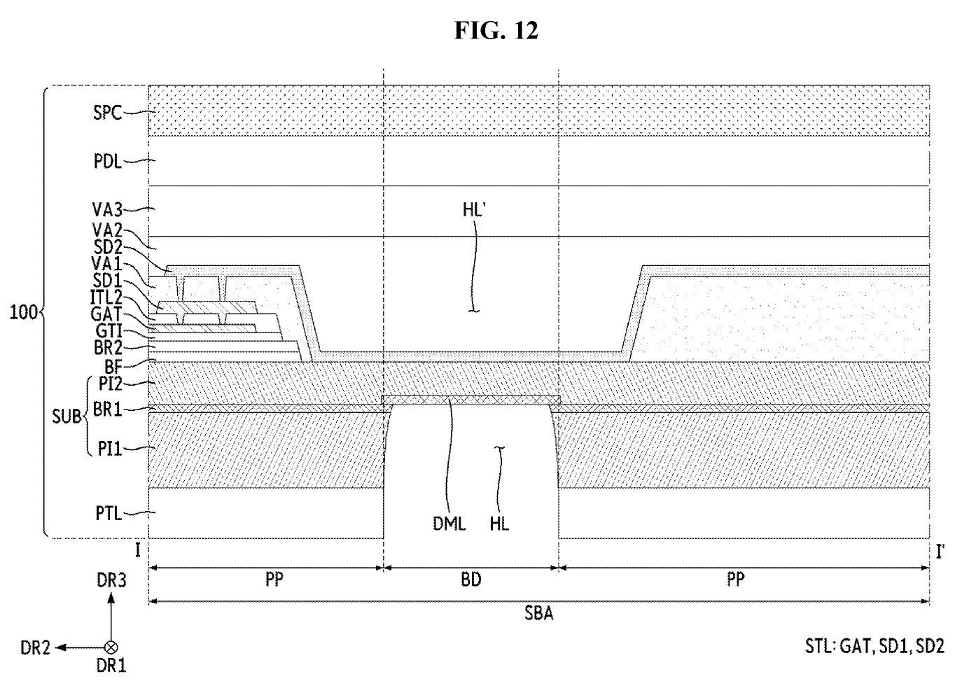

FIG. 12 is a cross-sectional view of the display device 10 according to still another embodiment, taken along the line I-I' of FIG. 2.

The display device 10 of FIG. 12 differs from the display device 10 of FIG. 7 described above in terms of the first base layer PI1 and a dummy layer DML, and the following description focuses on this difference.

Referring to FIG. 12, the substrate SUB may have the hole HL as a trench penetrating the first base layer PI1 and the first barrier layer BR1 in the bending area BD.

Referring to FIG. 12, the dummy layer DML may be further located on the bottom surface of the second base layer PI2 in the bending area BD. The dummy layer DML may be located between the second base layer PI2 and the hole HL of the substrate SUB. The dummy layer DML may be exposed through the hole HL of the substrate SUB. The dummy layer DML may be located in the substrate SUB to overlap the hole HL of the substrate SUB.

The dummy layer DML may be included in the substrate SUB. For example, the substrate SUB of FIG. 12 may include the first base layer PI1, the first barrier layer BR1, the dummy layer DML, and the second base layer PI2.

The dummy layer DML may include a heating layer. For example, the dummy layer DML may include a material capable of absorbing light, such as amorphous silicon (a-Si).

The process of forming the hole HL in the substrate SUB may be performed by a laser process. For example, laser light may be irradiated to the bottom surface of the first base layer PI1 in the bending area BD, and the substrate protective layer PTL, the first base layer PI1, and the first barrier layer BR1 to which the laser light is irradiated are removed in the bending area BD, thereby forming the hole HL in the substrate SUB. Specifically, when the laser light is irradiated to the substrate protective layer PTL, the first base layer PI1, and the first barrier layer BR1 along the edge of the bending area BD that defines the bending area BD, a portion of the substrate protective layer PTL (hereinafter, referred to as a first residual film) and a portion of the first base layer PI1 (hereinafter, referred to as a second residual film) surrounded by the bending area BD may be separated from a portion of the first base layer PI1 located outside the bending area BD, and a portion of the first barrier layer BR1 (hereinafter, referred to as a third residual film) surrounded by the bending area BD may be separated from a portion of the first barrier layer BR1 located outside the bending area BD. Thereafter, the first residual film, the second residual film, and the third residual film are removed, thereby forming the hole HL in the substrate SUB.

The laser light irradiated in the process of forming the hole HL in the substrate SUB described above may also be irradiated to the dummy layer DML. The dummy layer DML may absorb the laser light and release heat, and the heat generated from the dummy layer DML may be applied to the first residual film, the second residual film, and the third residual film. Accordingly, the first residual film, the second residual film, and the third residual film may be more easily separated from the substrate SUB.

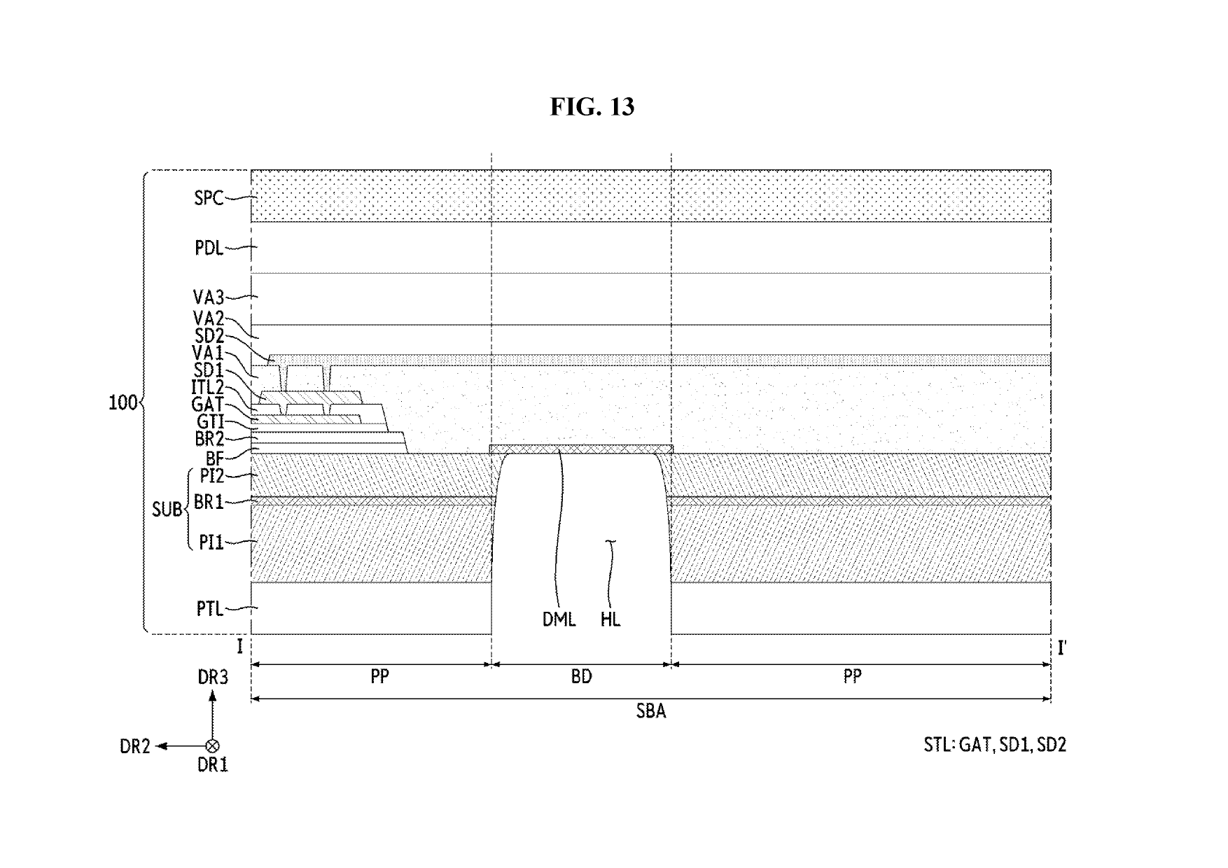

FIG. 13 is a cross-sectional view of the display device 10 according to still another embodiment, taken along the line I-I' of FIG. 2.

The display device 10 of FIG. 13 differs from the display device 10 of FIG. 9 described above in terms of the dummy layer DML, and the following description focuses on this difference.

Referring to FIG. 13, the substrate SUB may have the hole HL as a trench penetrating the first base layer PI1, the first barrier layer BR1, and the second base layer PI2 in the bending area BD.

Referring to FIG. 13, the dummy layer DML may be further located on the bottom surface of the first planarization layer VA1 in the bending area BD. For example, the dummy layer DML may be located on the top surface of the second base layer PI2 in the bending area BD. In other words, the dummy layer DML may be located between the first planarization layer VA1 and the hole HL of the substrate SUB. The dummy layer DML may be exposed through the hole HL of the substrate SUB. The dummy layer DML may be located on the substrate SUB to overlap the hole HL of the substrate SUB.

Because the dummy layer DML of FIG. 13 is substantially the same as the dummy layer DML of FIG. 12 described above, the description of the dummy layer DML of FIG. 13 refers to the description of the dummy layer DML of FIG. 12.

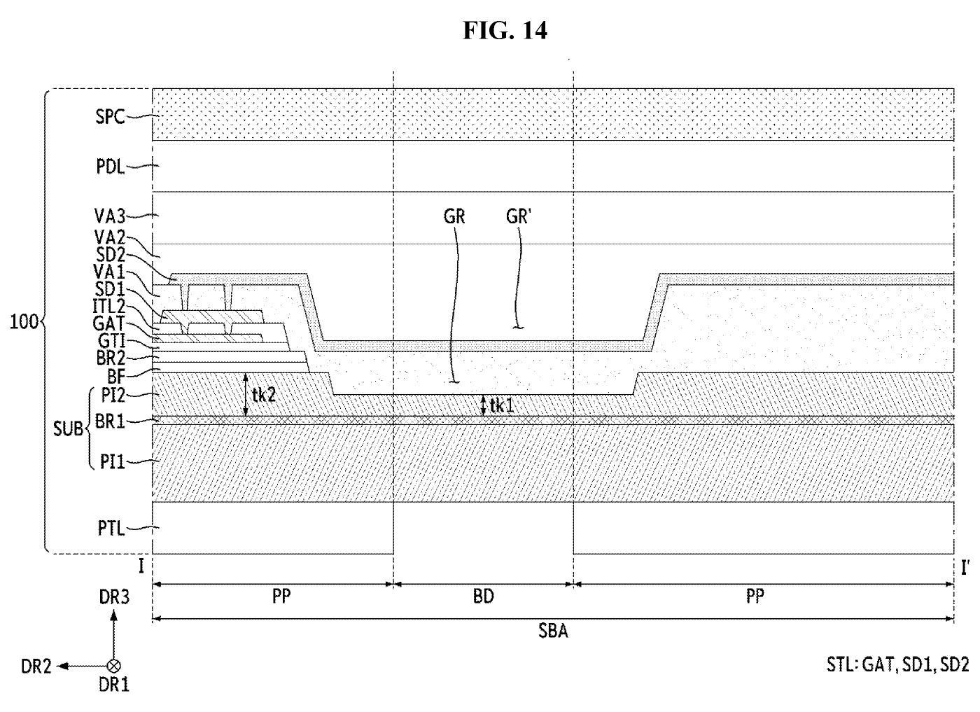

FIG. 14 is a cross-sectional view of the display device 10 according to still another embodiment, taken along the line I-I' of FIG. 2.

The display device 10 of FIG. 14 differs from the display device 10 of FIG. 9 described above in terms of the groove GR, and the following description focuses on this difference.

Referring to FIG. 14, the substrate SUB may have different thicknesses in the bending area BD and the peripheral area PP. For example, the thickness of the substrate SUB in the bending area BD may be less than the thickness of the substrate SUB in the peripheral area PP. Specifically, the thickness tk1 of the second base layer PI2 in the bending area BD may be less than the thickness tk2 of the second base layer PI2 in the peripheral area PP.

Referring to FIG. 14, the substrate SUB may include the first base layer PI1, the first barrier layer BR1, and the second base layer PI2, and in this case, the groove GR may be located in the top surface of the second base layer PI2. The groove GR of the second base layer PI2 may have a concave shape that is recessed in a direction (for example, reverse direction of the third direction DR3) (hereinafter, referred to as a third reverse direction) from the top surface of the second base layer PI2 toward the bottom surface of the second base layer PI2.

Further, referring to FIG. 14, in the bending area BD, a groove GR' of the first planarization layer VA1 may have a concave shape that is recessed in a direction (for example, the third reverse direction) from the top surface of the first planarization layer VA1 toward the bottom surface of the first planarization layer VA1.

As illustrated in FIG. 14, the first base layer PI1 and the first barrier layer BR1 may not have the groove GR and the hole HL in the bending area BD. In other words, the first base layer PI1 and the first barrier layer BR1 may not be cut in the bending area BD.

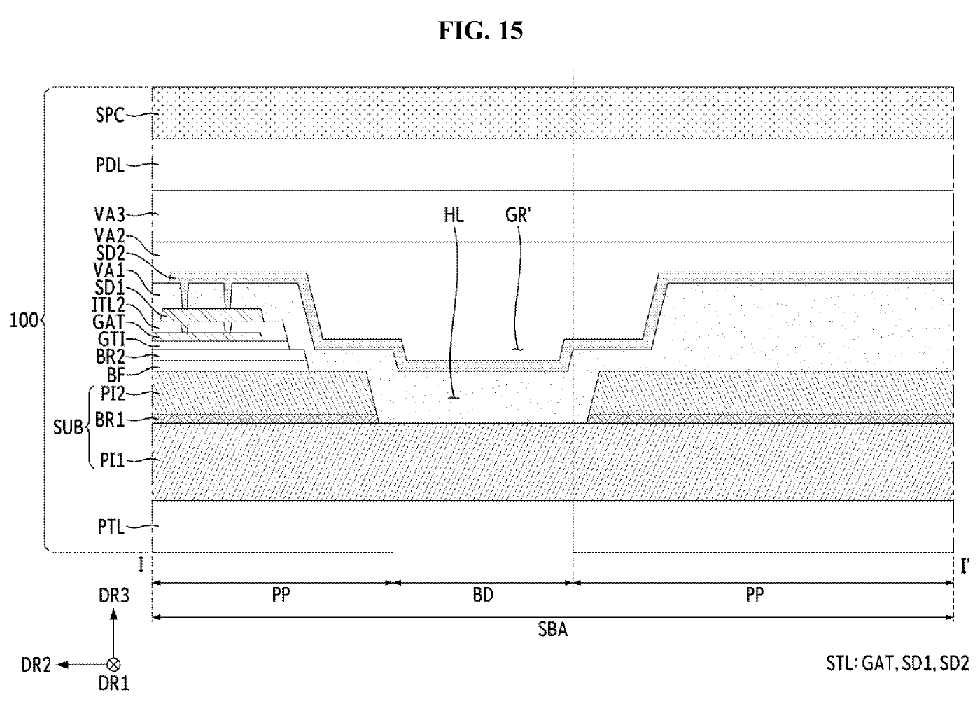

FIG. 15 is a cross-sectional view of the display device 10 according to still another embodiment, taken along the line I-I' of FIG. 2.

The display device 10 of FIG. 15 differs from the display device 10 of FIG. 14 described above in terms of the first barrier layer BR1 and the second base layer PI2, and the following description focuses on this difference.

Referring to FIG. 15, the substrate SUB may have different thicknesses in the bending area BD and the peripheral area PP. For example, the thickness of the substrate SUB in the bending area BD may be less than the thickness of the substrate SUB in the peripheral area PP.

Referring to FIG. 15, the substrate SUB may have the hole HL penetrating the first barrier layer BR1 and the second base layer PI2 in the bending area BD. The hole HL may overlap the first base layer PI1.

Further, referring to FIG. 15, in the bending area BD, the groove GR' of the first planarization layer VA1 may have a concave shape that is recessed in a direction (for example, the third reverse direction) from the top surface of the first planarization layer VA1 toward the bottom surface of the first planarization layer VA1.

In the bending area BD, the first base layer PI1 does not have the hole HL or the groove GR. For example, in the bending area BD, the first base layer PI1 may not be cut.

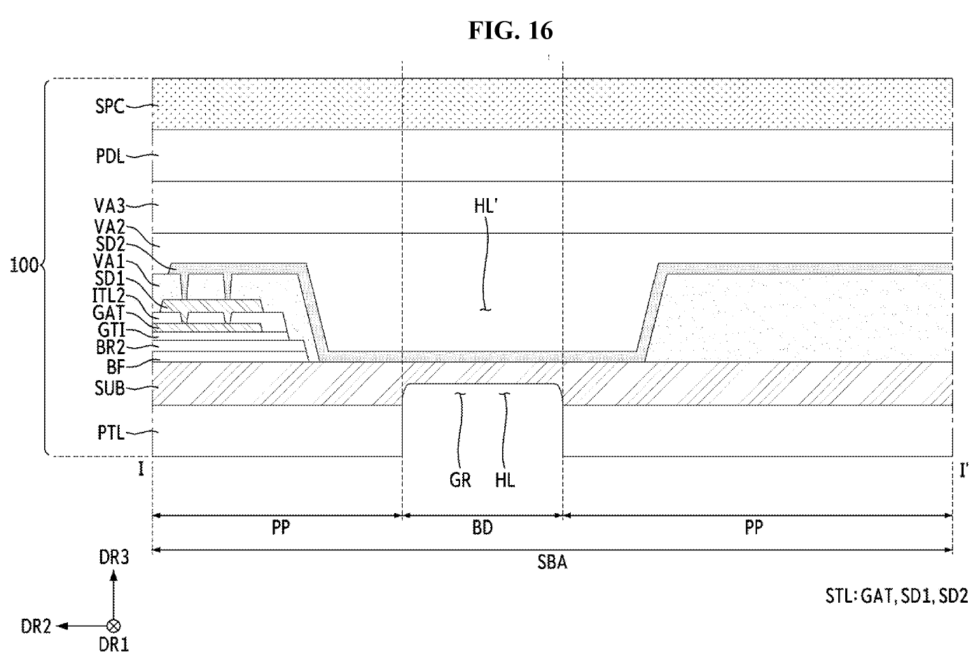

FIG. 16 is a cross-sectional view of the display device 10 according to still another embodiment, taken along the line I-I' of FIG. 2.

The display device 10 of FIG. 16 differs from the display device 10 of FIG. 7 described above in terms of the substrate SUB, and the following description focuses on this difference.

Referring to FIG. 16, the substrate SUB may be formed as a single layer. For example, the substrate SUB may include a base layer. The substrate SUB may include the same material as the first base layer PI1 described above. For example, the substrate SUB may be an insulating layer including an organic material. The substrate SUB may include flexible plastic. For example, the first base layer PI1 may include polyimide (PI), polyethylene naphthalate (PEN), polyethylene terephthalate (PET), polyarylate, polycarbonate (PC), polyetherimide (PEI), and/or polyethersulfone (PES).

Referring to FIG. 16, the substrate SUB may have at least one of the groove GR or the hole HL in the bending area BD. For example, as illustrated in FIG. 16, the hole HL and the groove GR may be located on the bottom surface of the substrate SUB. The groove GR of the substrate SUB may have a concave shape that is recessed in a direction (for example, the third direction DR3) from the bottom surface of the substrate SUB toward the top surface of the substrate SUB.

Further, referring to FIG. 16, the hole HL' of the first planarization layer VA1 may penetrate the first planarization layer VA1 in the third direction DR3 in the bending area BD.

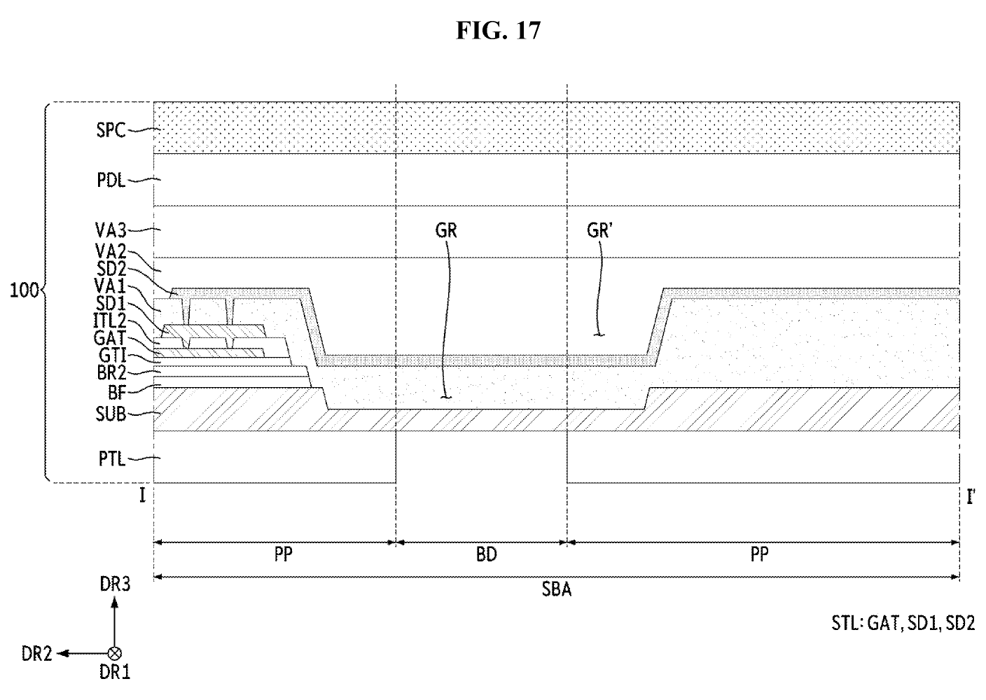

FIG. 17 is a cross-sectional view of the display device 10 according to still another embodiment, taken along the line I-I' of FIG. 2.

The display device 10 of FIG. 17 differs from the display device 10 of FIG. 14 described above in terms of the substrate SUB, and the following description focuses on this difference.

Referring to FIG. 17, the substrate SUB may be formed as a single layer. For example, the substrate SUB may include a base layer. This substrate SUB may include the same material as the first base layer PI1 described above. For example, the substrate SUB of FIG. 17 may include the same material as the substrate SUB of FIG. 16 described above.

Referring to FIG. 17, the substrate SUB may have at least one of the groove GR or the hole HL in the bending area BD. For example, as illustrated in FIG. 17, the groove GR may be located on the top surface of the substrate SUB. The groove GR of the substrate SUB may have a concave shape that is recessed in a direction (for example, the third reverse direction) from the top surface of the substrate SUB toward the bottom surface of the substrate SUB.

Further, referring to FIG. 17, in the bending area BD, the groove GR' of the first planarization layer VA1 may have a concave shape that is recessed in a direction (for example, the third reverse direction) from the top surface of the first planarization layer VA1 toward the bottom surface of the first planarization layer VA1.

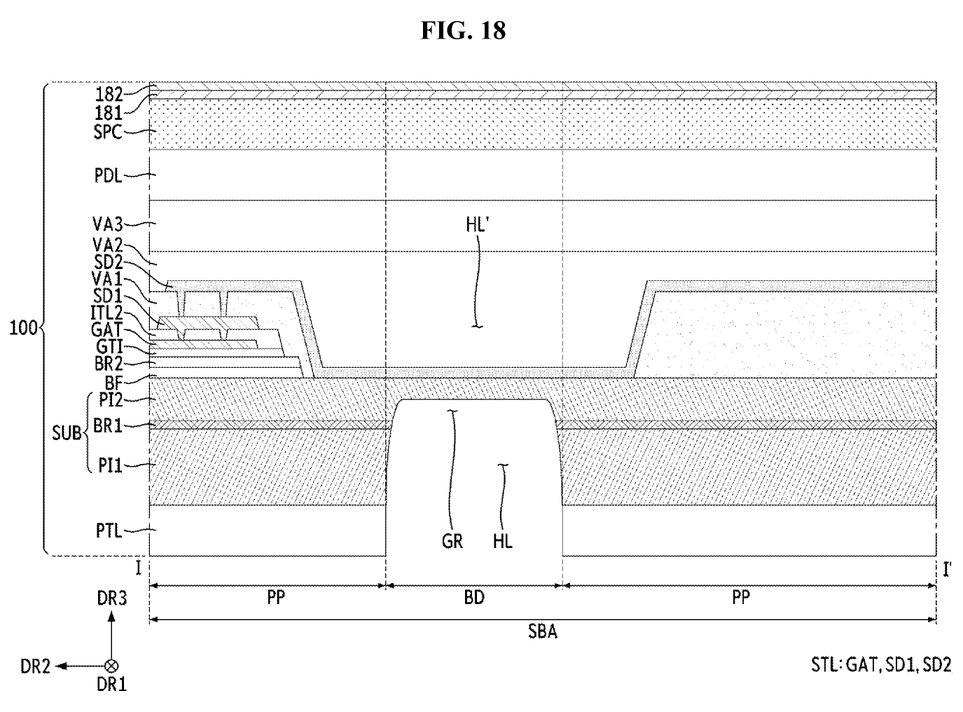

FIG. 18 is a cross-sectional view of the display device 10 according to still another embodiment, taken along the line I-I' of FIG. 2.

The display device 10 of FIG. 18 differs from the display device 10 of FIG. 7 described above in that at least one inorganic layer overlapping the bending area BD is further included, and the following description focuses on this difference.

Referring to FIG. 18, at least one inorganic layer may be located in the sub-region SBA of the display panel 100. The at least one inorganic layer may be located in the bending area BD of the sub-region SBA. For example, the at least one inorganic layer may be located in the bending area BD. In other words, a first inorganic layer 181 may be located on the spacer SPC in the sub-region SBA, and a second inorganic layer 182 may be located on the first inorganic layer 181 in the sub-region SBA. For example, the first inorganic layer 181 may be located between the spacer SPC and the second inorganic layer 182 in the sub-region SBA. The first inorganic layer 181 and the second inorganic layer 182 may be in contact (or direct contact) with each other.

According to one or more embodiments, the first inorganic layer 181 and the second inorganic layer 182 may be the same as the first encapsulation inorganic layer TFE1 and the second encapsulation inorganic layer TFE3 included in the encapsulation layer ENC described above, respectively. In other words, the first inorganic layer 181 may be the same as the first encapsulation inorganic layer TFE1, and the second inorganic layer 182 may be the same as the second encapsulation inorganic layer TFE3. In this case, the first inorganic layer 181 may be formed integrally with the first encapsulation inorganic layer TFE1, and the second inorganic layer 182 may be formed integrally with the second encapsulation inorganic layer TFE3. For example, the first encapsulation inorganic layer TFE1 may further extend to the sub-region SBA to overlap the bending area BD, and the second encapsulation inorganic layer TFE3 may further extend to the sub-region SBA to overlap the bending area BD, so that the first inorganic layer 181 and the second inorganic layer 182 may be formed in the sub-region SBA described above.

In this way, the first inorganic layer 181 and the second inorganic layer 182 are located in the sub-region SBA to overlap the bending area BD, so that the strain applied to the signal transmission line STL when the display panel 100 is bent may be reduced. For example, the first inorganic layer 181 and the second inorganic layer 182 have an elastic modulus considerably higher than the modulus of the signal transmission line STL (for example, the second source pattern layer SD2), so that the first inorganic layer 181 and the second inorganic layer 182 may reduce the strain applied to the second source pattern layer SD2 when the display panel 100 is bent. Accordingly, in the bending area BD, damage to the signal transmission line STL may be prevented more effectively.

The first inorganic layer 181 and the second inorganic layer 182 of FIG. 18 may be applied to at least one of the display devices 10 of the embodiments of FIGS. 7 to 17 described above. For example, the first inorganic layer 181 and the second inorganic layer 182 of FIG. 18 may be located on the spacer SPC of FIG. 12 and the spacer SPC of FIG. 13.

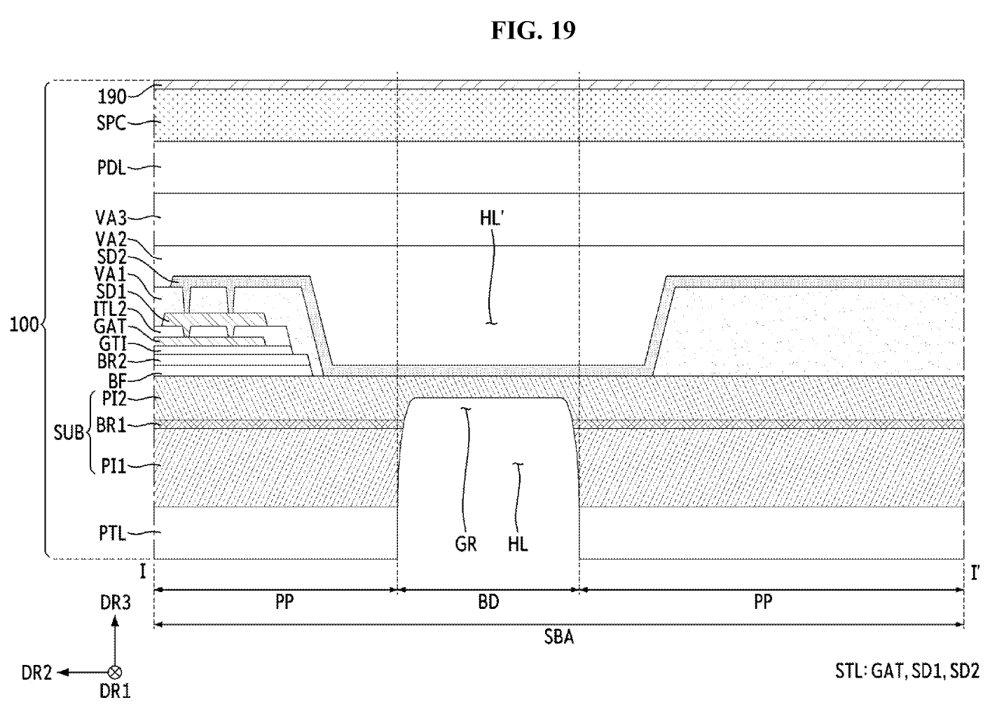

FIG. 19 is a cross-sectional view of the display device 10 according to still another embodiment, taken along the line I-I' of FIG. 2.

The display device 10 of FIG. 19 differs from the display device 10 of FIG. 7 described above in that at least one organic layer 190 overlapping the bending area BD is included, and the following description focuses on this difference.

Referring to FIG. 19, at least one organic layer 190 may be located in the sub-region SBA of the display panel 100. The at least one organic layer 190 may be located in the bending area BD of the sub-region SBA. For example, the at least one organic layer 190 may be located in the bending area BD. In other words, the organic layer 190 may be located on the spacer SPC in the sub-region SBA.

According to one or more embodiments, the organic layer 190 may be located in the main region MA of the display panel 100 as well as in the sub-region SBA. For example, the organic layer may be located on the entire surface of the substrate SUB.

In this way, the organic layer 190 is located in the sub-region SBA to overlap the bending area BD, so that the strain applied to the signal transmission line STL when the display panel 100 is bent may be reduced. For example, the organic layer 190 has an elastic modulus considerably higher than the modulus of the signal transmission line STL (for example, the second source pattern layer SD2), so that the organic layer 190 may reduce the strain applied to the second source pattern layer SD2 when the display panel 100 is bent. Accordingly, in the bending area BD, damage to the signal transmission line STL may be prevented more effectively.

The organic layer 190 of FIG. 19 may be applied to at least one of the display devices 10 of the embodiments of FIGS. 7 – 17 described above. For example, the organic layer 190 of FIG. 18 may be located on the spacer SPC of FIG. 12 and the spacer SPC of FIG. 13.

The display device 10 according to the embodiment may be applied to various electronic devices. An electronic device according to one or more embodiments may include the above-described display device 10, and may further include, in addition to the display device 10, a module or device having other additional functions.

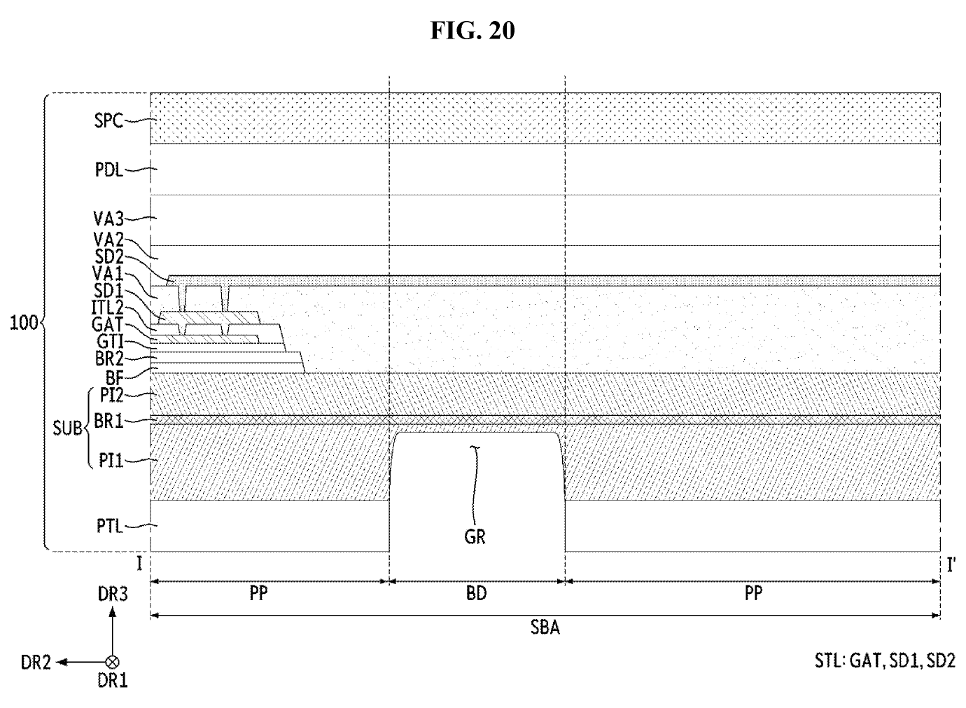

FIG. 20 is a cross-sectional view of the display device 10 according to still another embodiment, taken along the line I-I' of FIG. 2.

The display device 10 of FIG. 20 differs from the display device 10 of FIG. 9 described above in that the first base layer PI1 has the groove GR in the bending area BD, and the first barrier layer BR1 and the second base layer PI2 are further located in the bending area BD, and the following description focuses on these differences.

As shown in FIG. 20, the first base layer PI1 may have the groove GR in the bending area BD. In the bending area BD, the thickness of the substrate SUB may be reduced by the groove GR.

The first barrier layer BR1 and the second base layer PI2 may be further located in the bending area BD. For example, the first barrier layer BR1 and the second base layer PI2 do not have a groove and a hole in the bending area BD. In the bending area BD, the first barrier layer BR1 and the second base layer PI2 may overlap the groove GR.

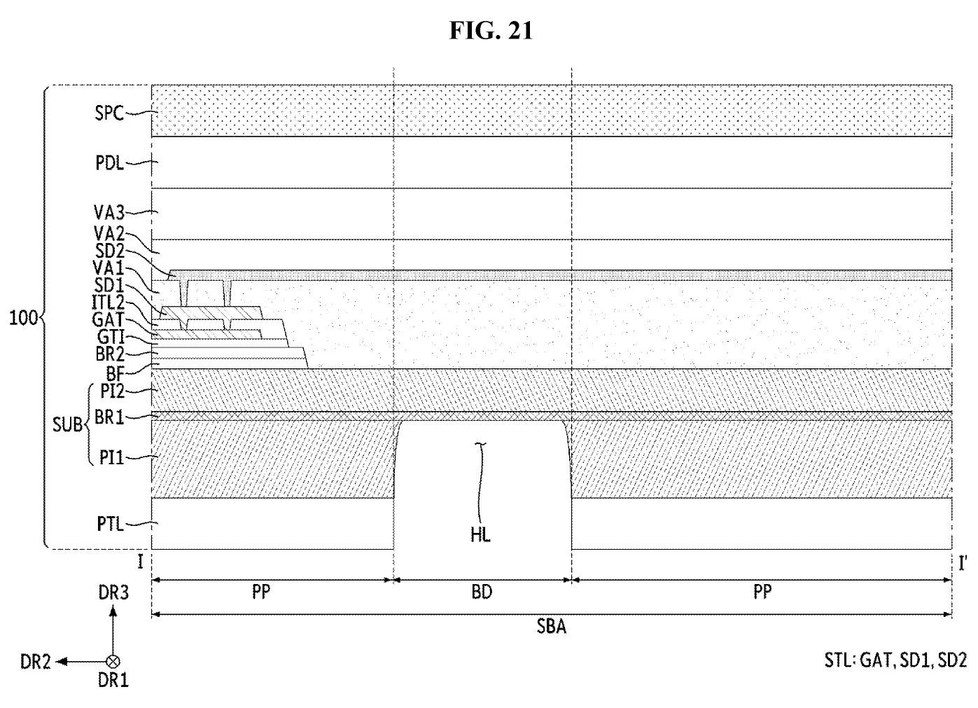

FIG. 21 is a cross-sectional view of the display device 10 according to still another embodiment, taken along the line I-I' of FIG. 2.

The display device 10 of FIG. 21 differs from the display device 10 of FIG. 20 described above in that the first base layer PI1 has the hole HL in the bending area BD, and the following description focuses on this difference.

As shown in FIG. 21, the first base layer PI1 may have the hole HL penetrating the first base layer PI1 in the third direction DR3 in the bending area BD. In the bending area BD, the thickness of the substrate SUB may be reduced by the hole HL.

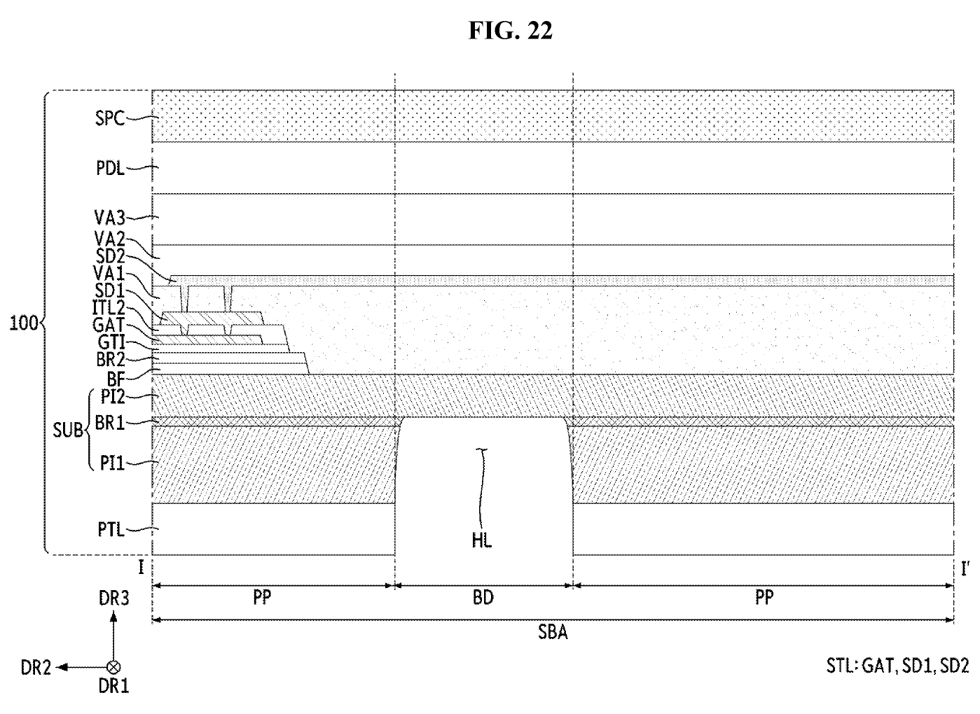

FIG. 22 is a cross-sectional view of the display device 10 according to still another embodiment, taken along the line I-I' of FIG. 2.

The display device 10 of FIG. 22 differs from the display device 10 of FIG. 20 described above in that the first base layer PI1 and the first barrier layer BR1 have the hole HL in the bending area BD, and the following description focuses on this difference.

As shown in FIG. 22, in the bending area BD, the substrate SUB may have the hole HL penetrating the first base layer PI1 and the first barrier layer BR1 in the third direction DR3. In the bending area BD, the thickness of the substrate SUB may be reduced by the hole HL.

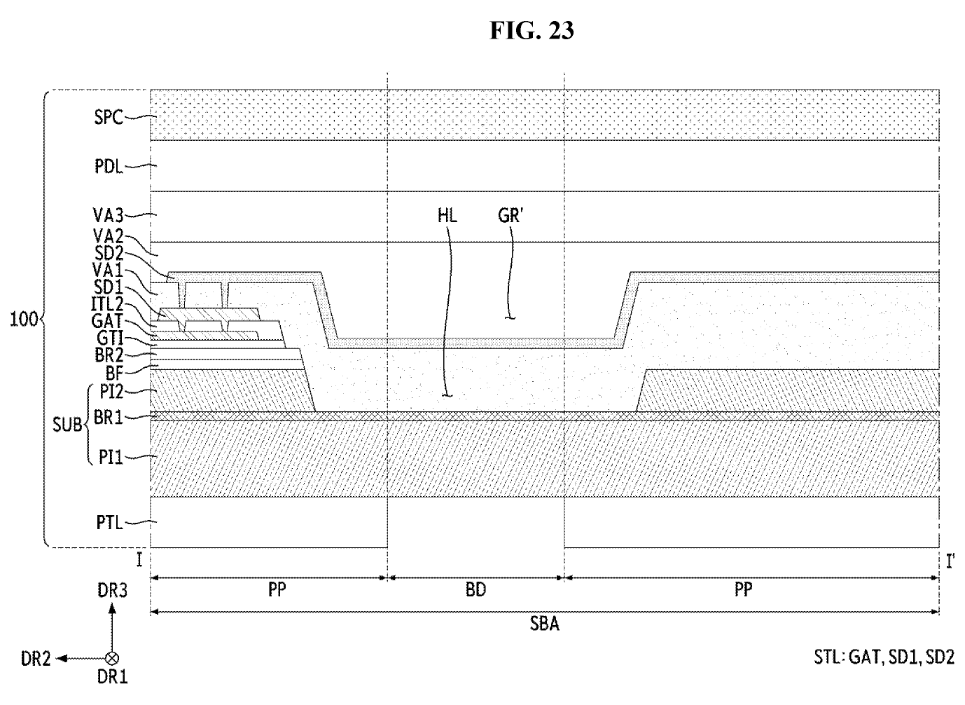

FIG. 23 is a cross-sectional view of the display device 10 according to still another embodiment, taken along the line I-I' of FIG. 2.

The display device 10 of FIG. 23 differs from the display device 10 FIG. 15 described above in the shape of the second base layer PI2 and in that the first barrier layer BR1 is further located in the bending area BD, and the following description focuses on these differences.

As illustrated in FIG. 23, the first barrier layer BR1 may be further located in the bending area BD. For example, in the bending area BD, the first barrier layer BR1 does not have a groove and a hole. In the bending area BD, the first barrier layer BR1 may overlap the groove HL and the groove GR'.

Further, as illustrated in FIG. 23, one end of the second base layer PI2 adjacent to the hole HL may be aligned with the end of the buffer layer BF.

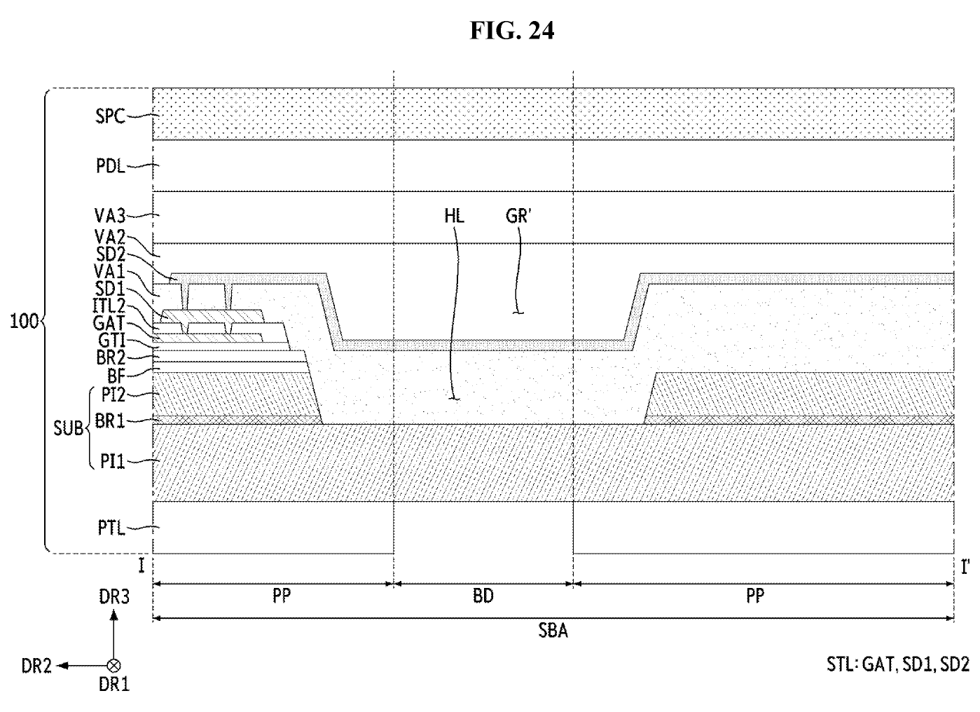

FIG. 24 is a cross-sectional view of the display device 10 according to still another embodiment, taken along the line I-I' of FIG. 2.

The display device 10 of FIG. 24 differs from the display device 10 of FIG. 15 described above in the shapes of the first barrier layer BR1 and the second base layer PI2, and the following description focuses on this difference.

As illustrated in FIG. 24, one end of the first barrier layer BR1 adjacent to the hole HL and one end of the second base layer PI2 adjacent to the hole HL may each be aligned with the end of the buffer layer BF.

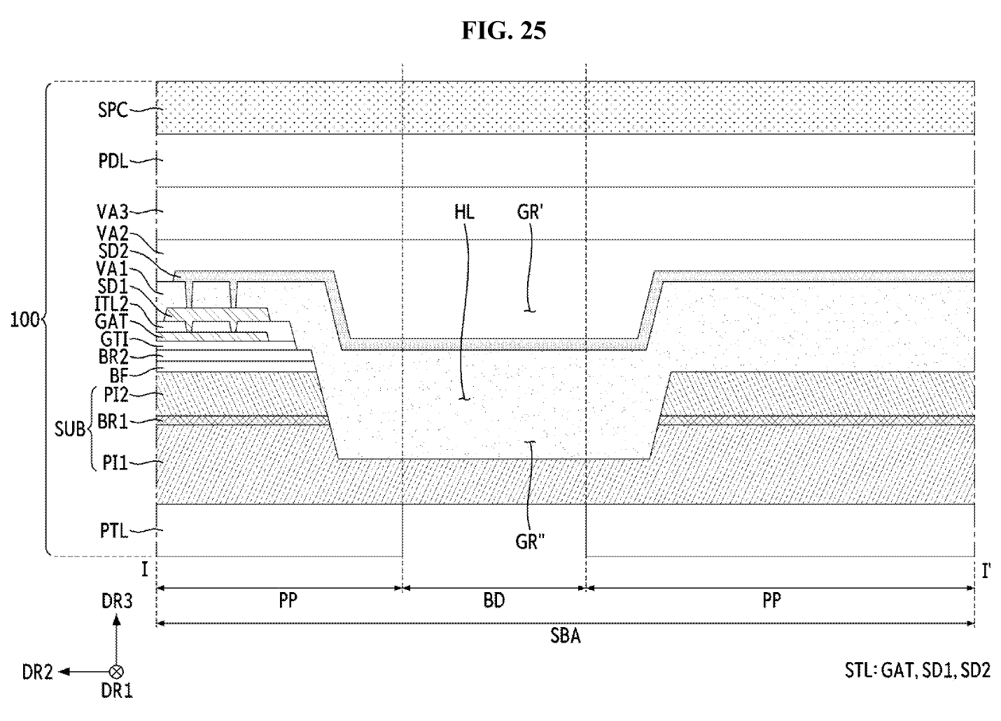

FIG. 25 is a cross-sectional view of the display device 10 according to still another embodiment, taken along the line I-I' of FIG. 2.

The display device 10 of FIG. 25 differs from the display device 10 of FIG. 24 described above in the shape of the first base layer PI1, and the following description focuses on this difference.

As illustrated in FIG. 25, the first base layer PI1 may have a groove GR'' formed on the surface thereof. The groove GR'' of the first base layer PI1 may be located in the bending area BD and overlap the hole HL and groove GR' thereabove.

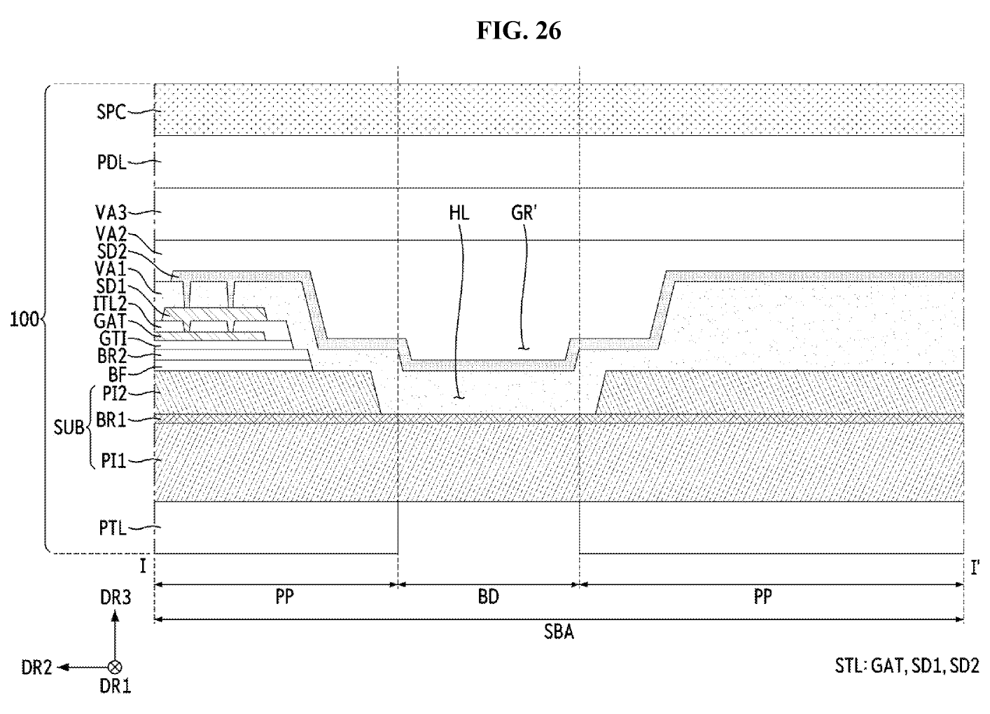

FIG. 26 is a cross-sectional view of the display device 10 according to still another embodiment, taken along the line I-I' of FIG. 2.

The display device 10 of FIG. 26 differs from the display device 10 of FIG. 15 described above in that the first barrier layer BR1 is further located in the bending area BD, and the following description focuses on this difference.

As shown in FIG. 25, the first barrier layer BR1 may be further located in the bending area BD. For example, in the bending area BD, the first barrier layer BR1 does not have a groove and a hole. In the bending area BD, the first barrier layer BR1 may overlap the hole HL and the groove GR'.

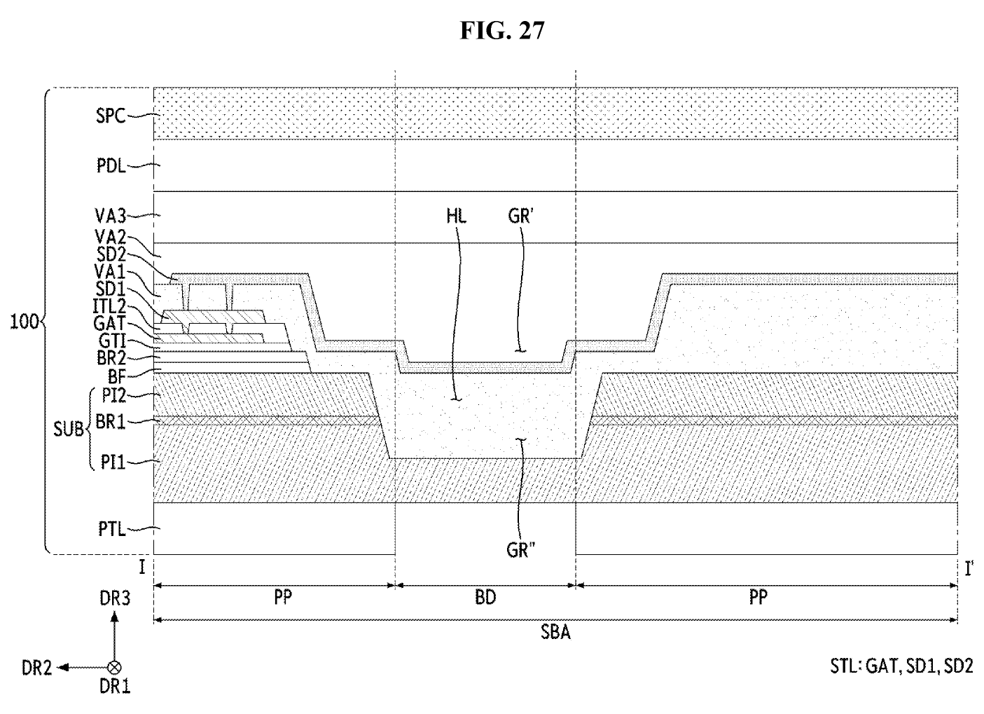

FIG. 27 is a cross-sectional view of the display device 10 according to still another embodiment, taken along the line I-I' of FIG. 2.

The display device 10 of FIG. 27 differs from the display device 10 of FIG. 15 described above in that the first base layer PI1 further includes the groove GR'' in the bending area BD, and the following description focuses on this difference.

As shown in FIG. 27, in the bending area BD, the first base layer PI1 may further have the groove GR'' formed on the top surface thereof. The groove GR'' of the first base layer PI1 may overlap the hole HL and groove GR' thereabove.

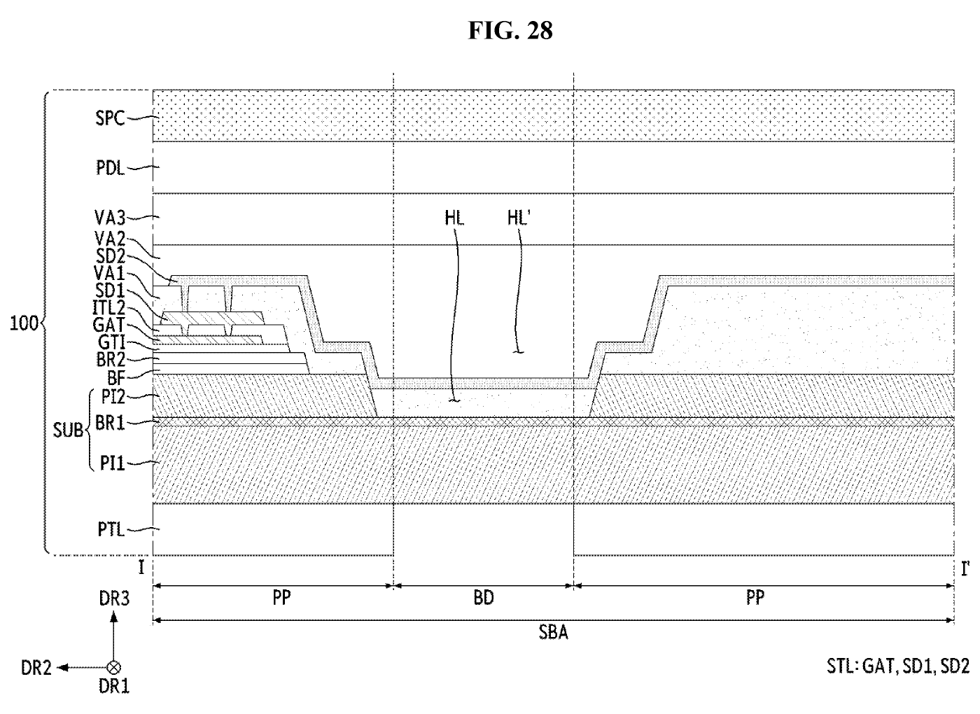

FIG. 28 is a cross-sectional view of the display device 10 according to still another embodiment, taken along the line I-I' of FIG. 2.

The display device 10 of FIG. 28 differs from the display device 10 of FIG. 26 described above in the shape of the second source pattern layer SD2, and the following description focuses on this difference.

As illustrated in FIG. 28, in the bending area BD, the second source pattern layer SD2 may be in contact with the end of the second base layer PI2. For example, in the bending area BD, the second source pattern layer SD2 may be in contact with the end of the second base layer PI2 adjacent to the bending area BD.

Further, as illustrated in FIG. 28, in the bending area BD, the first planarization layer VA1 may have the hole HL' penetrating the first planarization layer VA1. The hole HL' of the first planarization layer VA1 may overlap the hole HL of the substrate SUB. A part of the first planarization layer VA1 may be located in the hole HL of the substrate SUB.

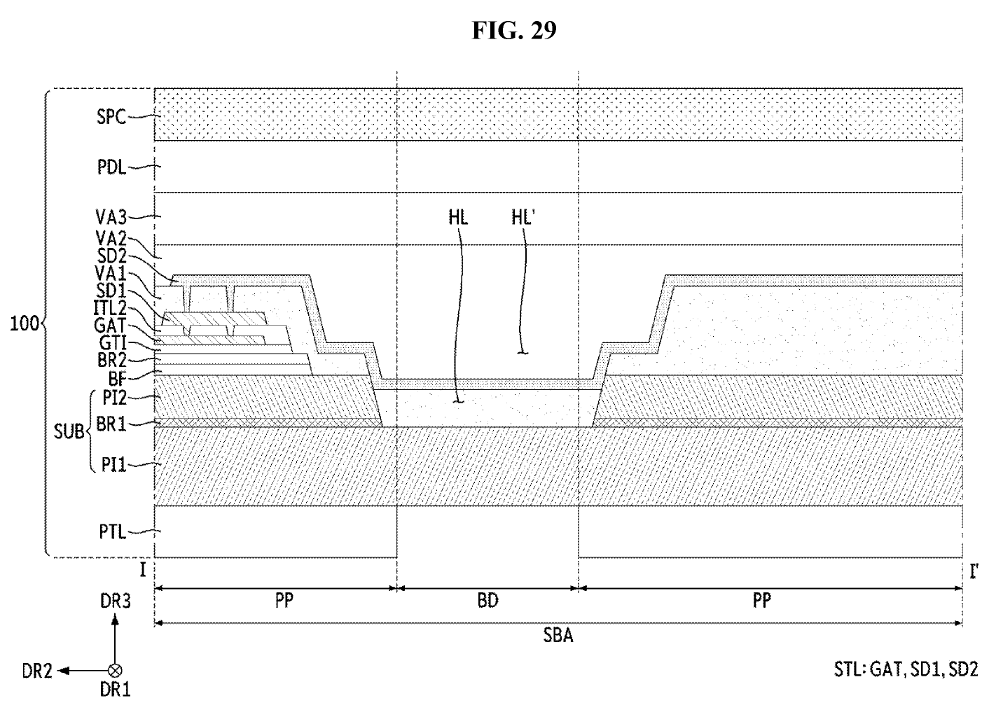

FIG. 29 is a cross-sectional view of the display device 10 according to still another embodiment, taken along the line I-I' of FIG. 2.

The display device 10 of FIG. 29 differs from the display device 10 of FIG. 28 described above in that the first barrier layer BR1 is not formed in the bending area BD, and the following description focuses on this difference.

As illustrated in FIG. 29, in the bending area BD, the substrate SUB may have the hole HL penetrating the first barrier layer BR1 and the second base layer PI2. Accordingly, the first barrier layer BR1 and the second base layer PI2 may not be located in the bending area BD.

Further, as illustrated in FIG. 29, in the bending area BD, the first planarization layer VA1 may have the hole HL' penetrating the first planarization layer VA1. The hole HL' of the first planarization layer VA1 may overlap the hole HL of the substrate SUB. A part of the first planarization layer VA1 may be located in the hole HL of the substrate SUB.

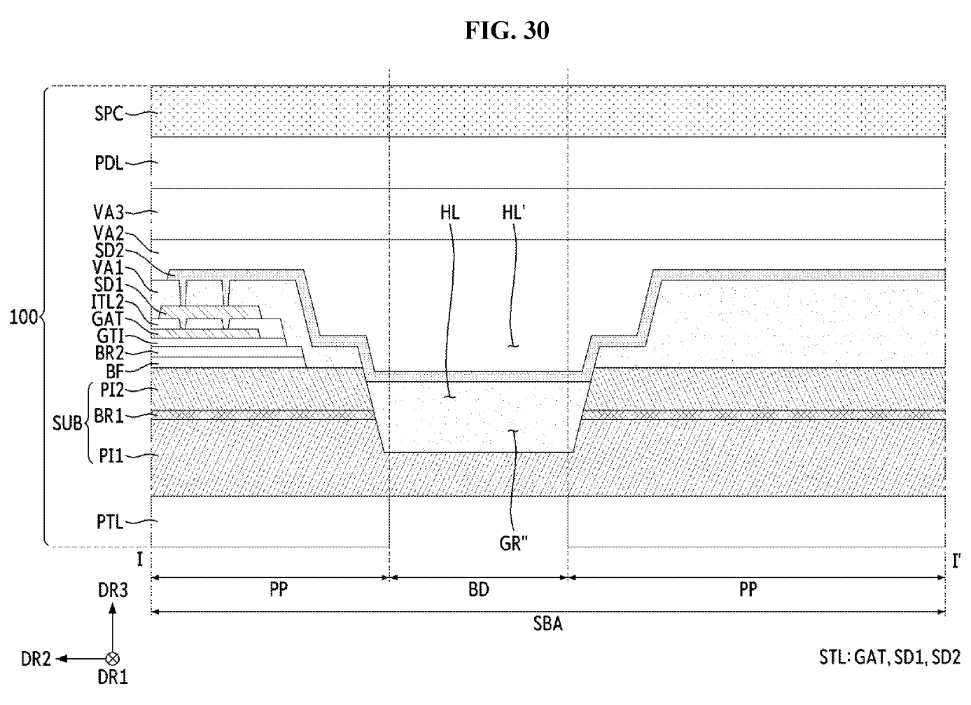

FIG. 30 is a cross-sectional view of the display device 10 according to still another embodiment, taken along the line I-I' of FIG. 2.

The display device 10 of FIG. 30 differs from the display device 10 of FIG. 29 described above in that the first base layer PI1 has the groove GR'' in the bending area BD, and the following description focuses on this difference.

As illustrated in FIG. 30, in the bending area BD, the first base layer PI1 may have the groove GR'' formed on the top surface thereof. The groove GR'' of the first base layer PI1 may overlap the hole HL and the groove GR' on the top surface thereof.

Further, as illustrated in FIG. 30, in the bending area BD, the first planarization layer VA1 may have the hole HL' penetrating the first planarization layer VA1. The hole HL' of the first planarization layer VA1 may overlap the hole HL and the groove GR of the substrate SUB. A part of the first planarization layer VA1 may be located in the hole HL and groove GR of the substrate SUB.

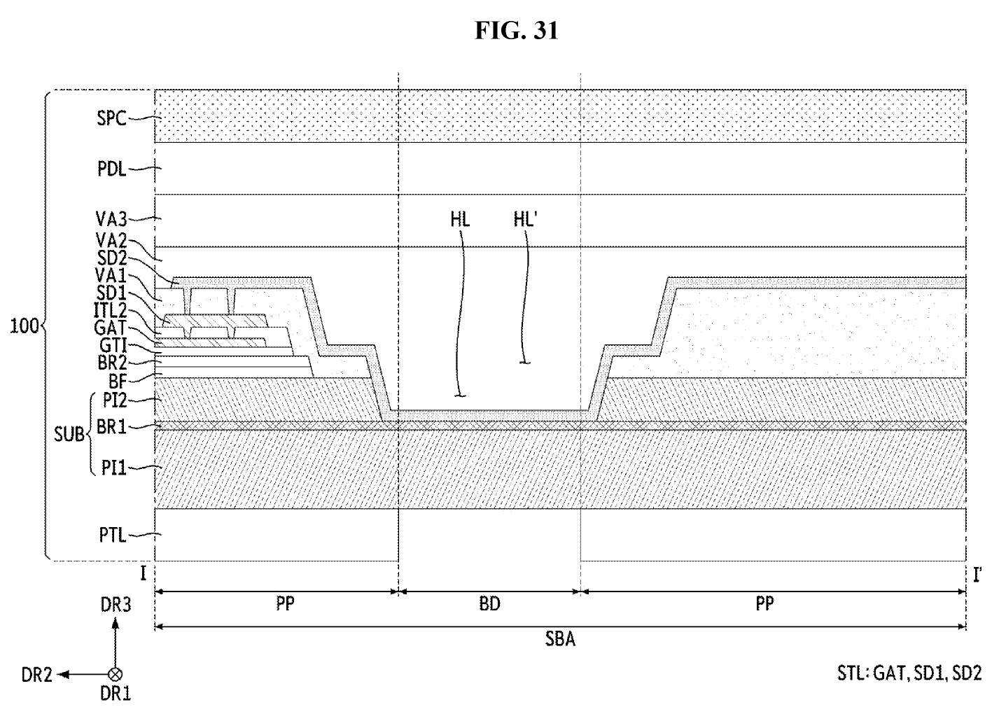

FIG. 31 is a cross-sectional view of the display device 10 according to still another embodiment, taken along the line I-I' of FIG. 2.

The display device 10 of FIG. 31 differs from the display device 10 of FIG. 28 described above in that the second source pattern layer SD2 and the first barrier layer BR1 are in contact with each other in the bending area BD, and the following description focuses on this difference.

As illustrated in FIG. 31, the second source pattern layer SD2 and the first barrier layer BR1 may be in contact with each other in the bending area BD. Further, the second source pattern layer SD2 and the second base layer PI2 (for example, the end of the second base layer PI2 adjacent to the bending area BD) may be in contact with each other in the bending area BD.

Further, as illustrated in FIG. 31, in the bending area BD, the first planarization layer VA1 may have the hole HL' penetrating the first planarization layer VA1. The hole HL' of the first planarization layer VA1 may overlap the hole HL of the substrate SUB.

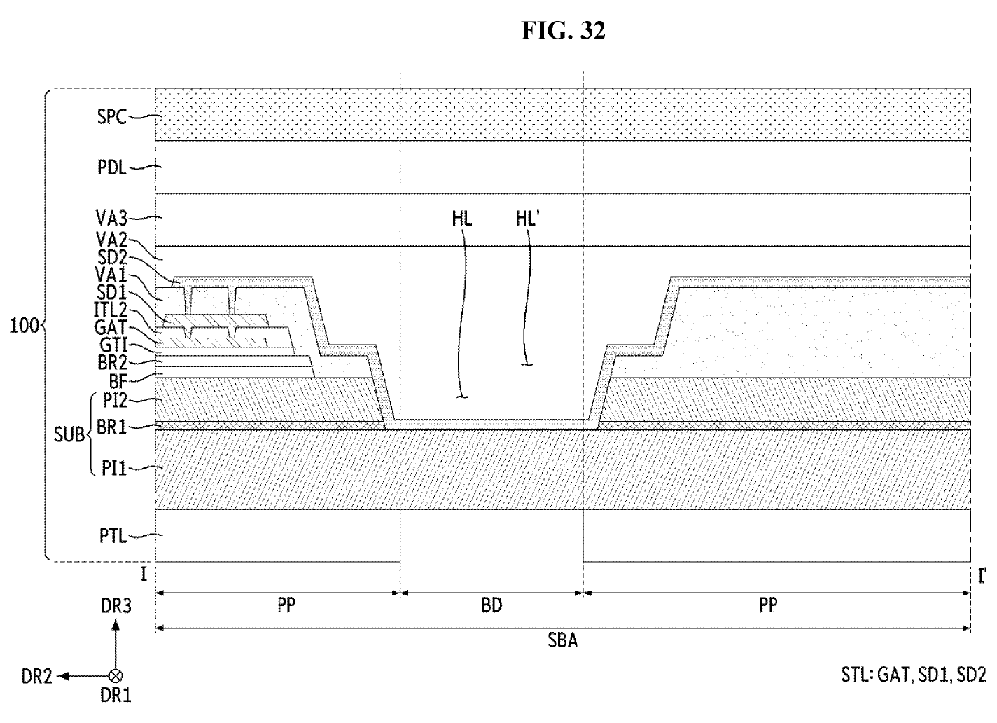

FIG. 32 is a cross-sectional view of the display device 10 according to still another embodiment, taken along the line I-I' of FIG. 2.

The display device 10 of FIG. 32 differs from the display device 10 of FIG. 29 described above in that the second source pattern layer SD2 and the first base layer PI1 are in contact with each other in the bending area BD, and the following description focuses on this difference.

As shown in FIG. 32, the second source pattern layer SD2 and the first base layer PI1 may be in contact with each other in the bending area BD. Further, the second source pattern layer SD2, the first barrier layer BR1 (for example, the end of the first barrier layer BR1 adjacent to the bending area BD), and the second base layer PI2 (for example, the end of the second base layer PI2 adjacent to the bending area BD) may be in contact with each other in the bending area BD.

Further, as illustrated in FIG. 32, in the bending area BD, the first planarization layer VA1 may have the hole HL' penetrating the first planarization layer VA1. The hole HL' of the first planarization layer VA1 may overlap the hole HL of the substrate SUB.

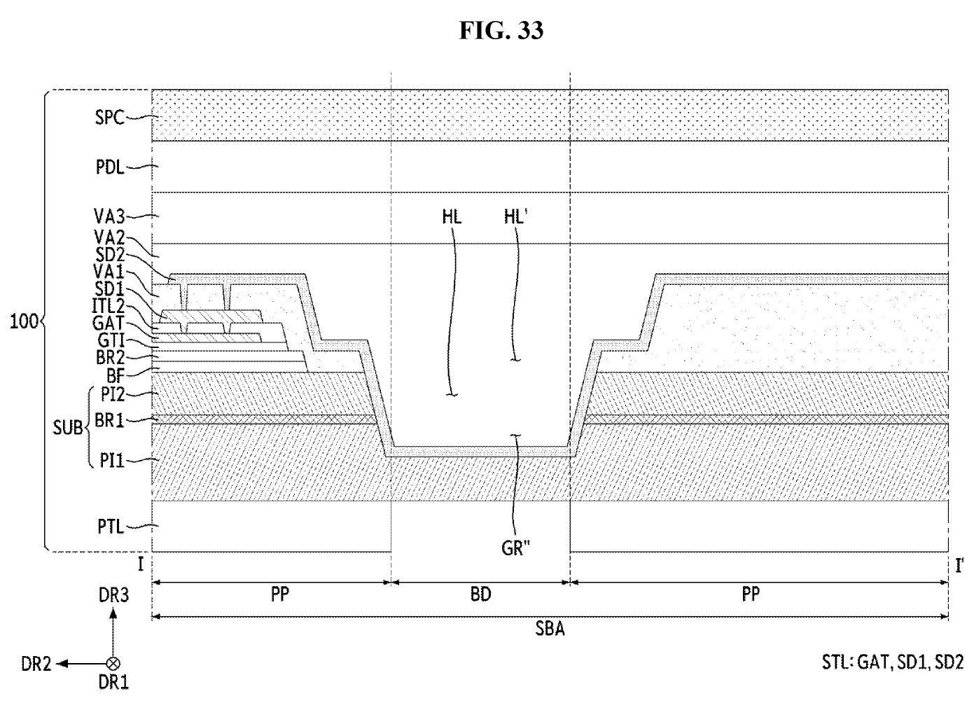

FIG. 33 is a cross-sectional view of the display device 10 according to still another embodiment, taken along the line I-I' of FIG. 2.

The display device 10 of FIG. 33 differs from the display device 10 of FIG. 30 described above in that the second source pattern layer SD2 and the first base layer PI1 are in contact with each other in the bending area BD, and the following description focuses on this difference.

As illustrated in FIG. 33, the second source pattern layer SD2 may be located in the groove GR'' of the first base layer PI1 in the bending area BD. In this case, the second source pattern layer SD2 may be in contact with the first base layer PI1 in the groove GR'' of the first base layer PI1.

Further, as illustrated in FIG. 33, in the bending area BD, the first planarization layer VA1 may have the hole HL' penetrating the first planarization layer VA1. The hole HL' of the first planarization layer VA1 may overlap the hole HL and groove GR'' of the substrate SUB. A part of the first planarization layer VA1 may be located in the hole HL and groove GR'' of the substrate SUB.

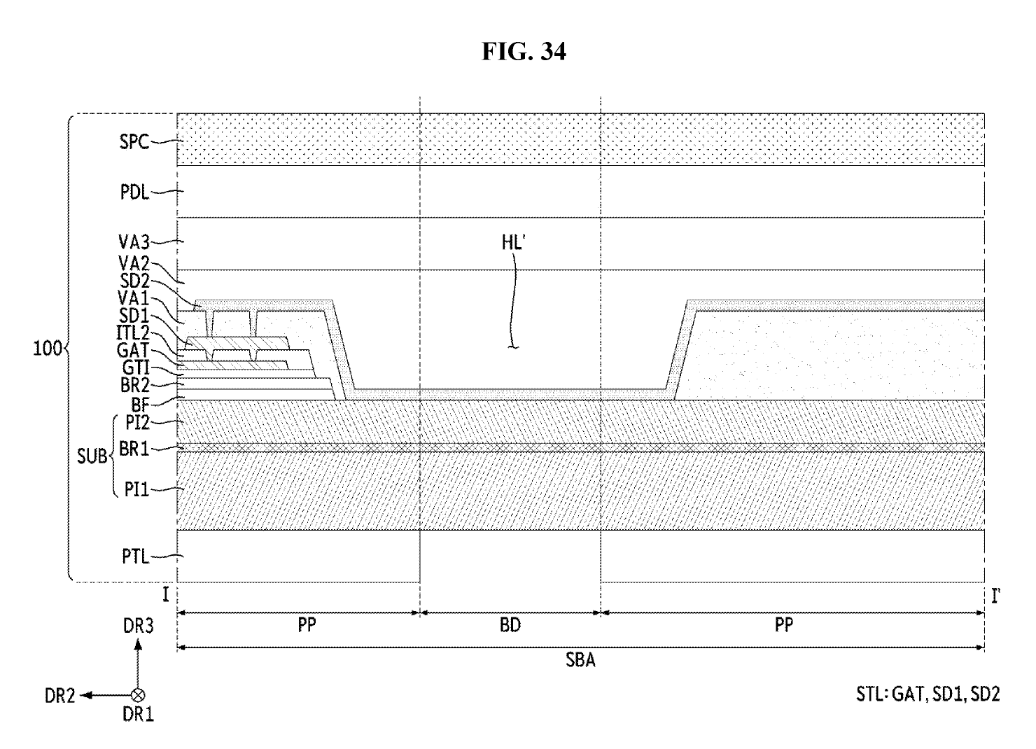

FIG. 34 is a cross-sectional view of the display device 10 according to still another embodiment, taken along the line I-I' of FIG. 2.

The display device 10 of FIG. 34 differs from the display device 10 of FIG. 12 described above in that the first base layer PI1 and the first barrier layer BR1 are further located in the bending area BD, and the dummy layer DML is omitted, and the following description focuses on these differences.

The first base layer PI1 and the first barrier layer BR1 may be further located in the bending area BD. For example, in the bending area BD, the first base layer PI1 and the first barrier layer BR1 do not have a groove and a hole. In the bending area BD, the first base layer PI1 and the first barrier layer BR1 may overlap the hole HL'.

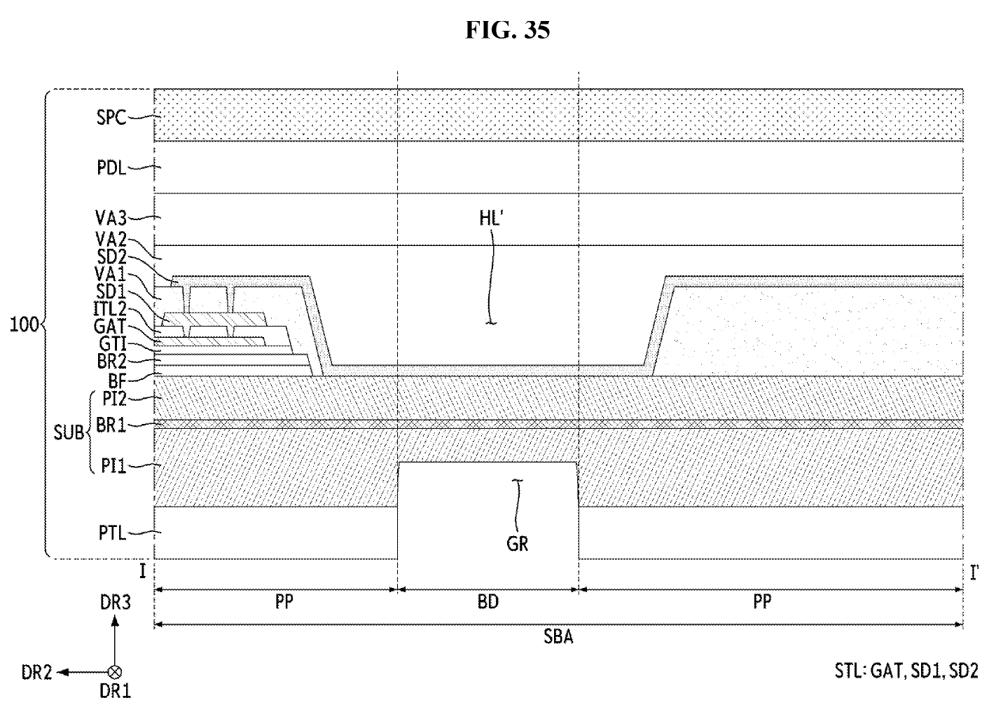

FIG. 35 is a cross-sectional view of the display device 10 according to still another embodiment, taken along the line I-I' of FIG. 2.

The display device 10 of FIG. 35 differs from the display device of FIG. 34 described above in the shape of the first base layer PI1, and the following description focuses on this difference.

As shown in FIG. 35, in the bending area BD, the first base layer PI1 may have the groove GR formed on the bottom surface thereof. The groove of the first base layer PI1 may overlap the hole HL'.

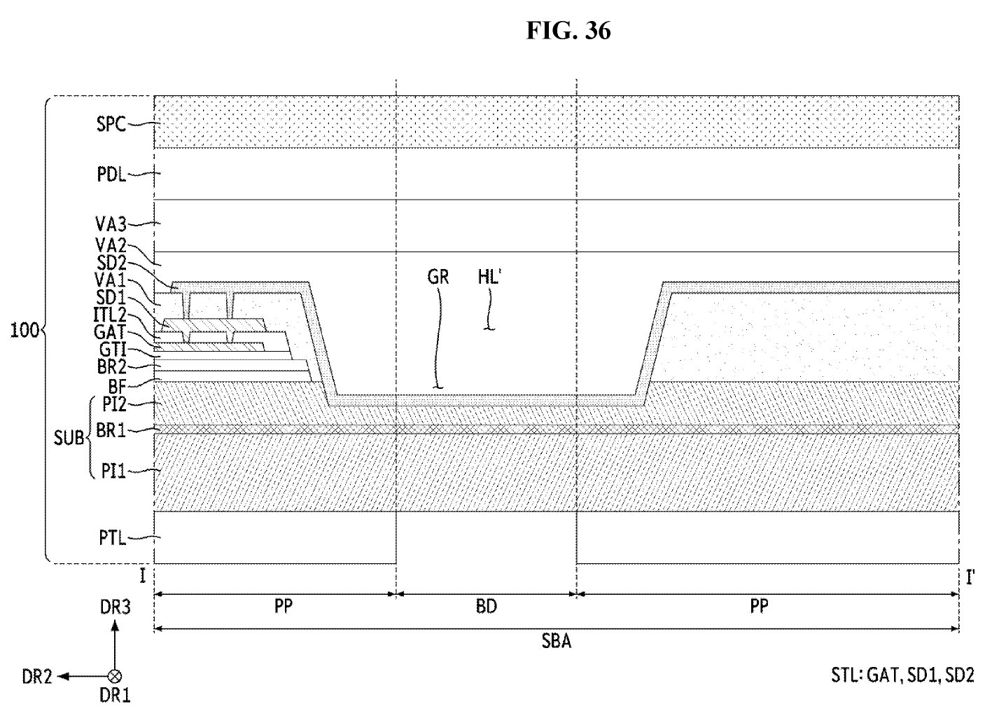

FIG. 36 is a cross-sectional view of the display device 10 according to still another embodiment, taken along the line I-I' of FIG. 2.

The display device 10 of FIG. 36 differs from the display device of FIG. 34 described above in the shapes of the second source pattern layer SD2 and the second base layer PI2, and the following description focuses on this difference.

As illustrated in FIG. 36, in the bending area BD, the second base layer PI2 may have the groove GR formed on the top surface thereof.

The second source pattern layer SD2 may be in contact with the second base layer PI2 in the groove GR of the second base layer PI2.

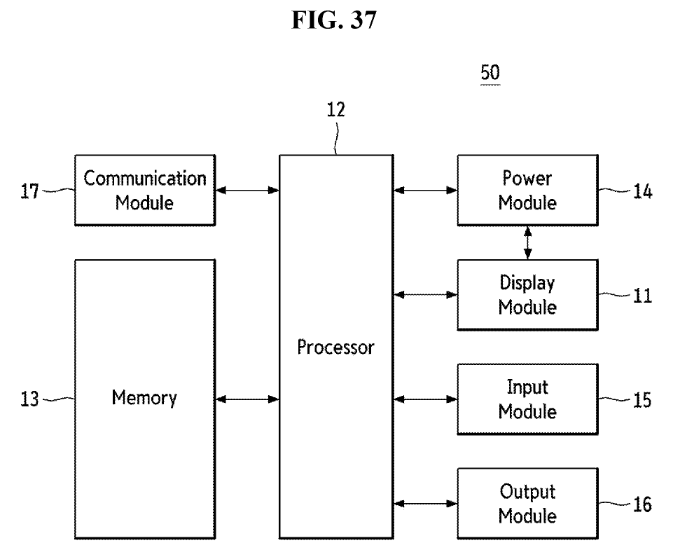

FIG. 37 is a block diagram of an electronic device according to one or more embodiments. Referring to FIG. 37, an electronic device 50 according to one or more embodiments may include a display module 11, a processor 12, a memory 13, and a power module 14. The electronic device 50 may further include an input module 15, an output module (e.g., a non-image output module) 16, and/or a communication module 17.

The electronic device 50 may output various information in the form of images through the display module 11. When the processor 12 executes an application stored in the memory 13, image information provided by the application may be provided to a user through the display module 11. The power module 14 may include a power supply module, such as a power adapter or a battery device, and a power conversion module that converts the power supplied by the power supply module to generate the power required for the operation of the electronic device 50. The input module 15 may provide input information to the processor 12 and/or the display module 11. The non-image output module 16 may serve to receive information other than images, such as sound, haptics, luminescence, etc., sent from the processor 12, and provide it to the user. The communication module 17 is a module responsible for the transmission and reception of information between the electronic device 50 and an external device, and may include a receiver and a transmitter.

At least one of each of the components of the above-described electronic device 50 may be included in the display device according to one or more embodiments described above. Further, some of individual modules functionally included in one module may be included in the display device and some others may be provided separately from the display device. For example, the display device may include the display module 11, and the processor 12, the memory 13, and the power module 14 may be provided in the form of other devices in the electronic device 50 other than the display device.

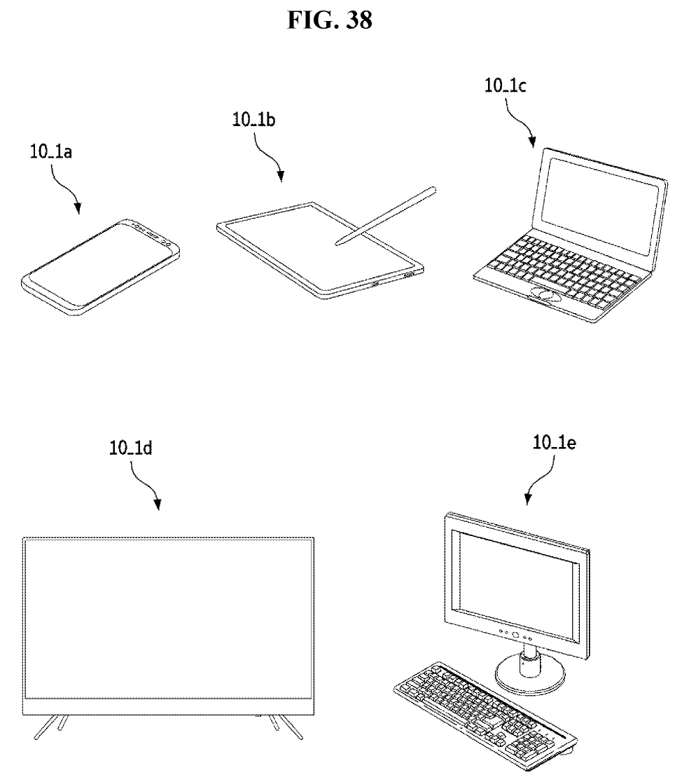

FIGS. 38, 39, and 40 are schematic diagrams illustrating electronic devices according to various embodiments. FIGS. 38 – 40 illustrate examples of various electronic devices to which the display device 10 according to the above-described embodiments are applied.

FIG. 38 shows a smartphone 10_1a, a tablet PC 10_1b, a laptop 10_1c, a TV 10_1d, and a desktop monitor 10_1e as examples of electronic devices.

The smartphone 10_1a may include a communication module and an input module such as a touch sensor in addition to the display module 11. The smartphone 10_1a may process the information received through the communication module or input module and display the processed information through the display module of the display device.

Each of the tablet PC 10_1b, the laptop 10_1c, the TV 10_1d, and the desktop monitor 10_1e may include a display module and an input module, similarly to the smartphone 10_1a, and may further include a communication module in some cases.

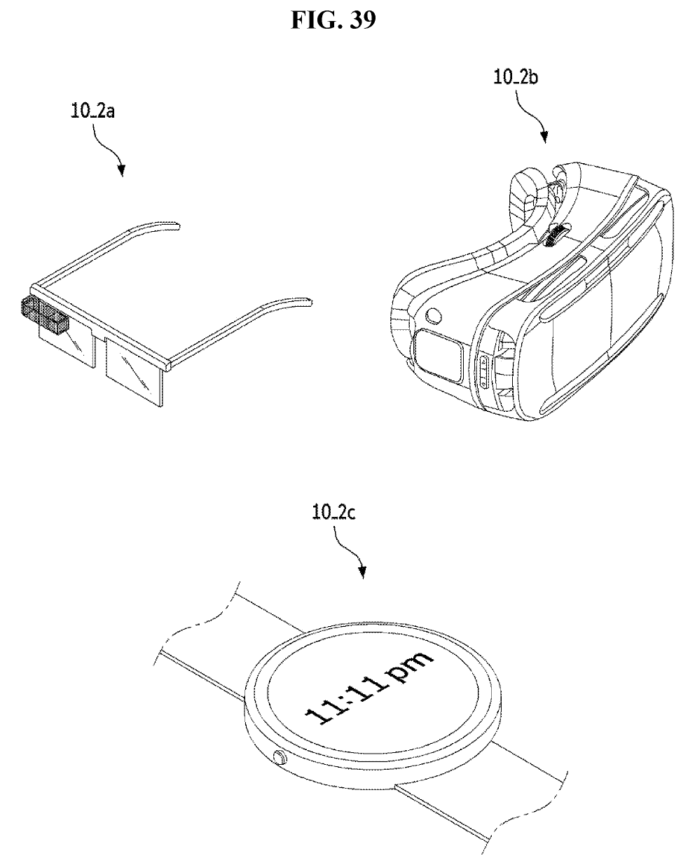

FIG. 39 illustrates a case in which an electronic device including a display module is applied to a wearable electronic device. The wearable electronic device may be smart glasses 10_2a, a head mounted display 10_2b, a smart watch 10_2c, and/or the like.

The smart glasses 10_2a and the head mounted display 10_2b may include a display module that outputs a display image and a reflector that reflects the outputted display image to provide it to the user's eyes, thereby providing the user with a virtual reality or augmented reality screen.

The smart watch 10_2c may include a biometric sensor as an input device, and may provide biometric information recognized through the biometric sensor to the user through a display module.

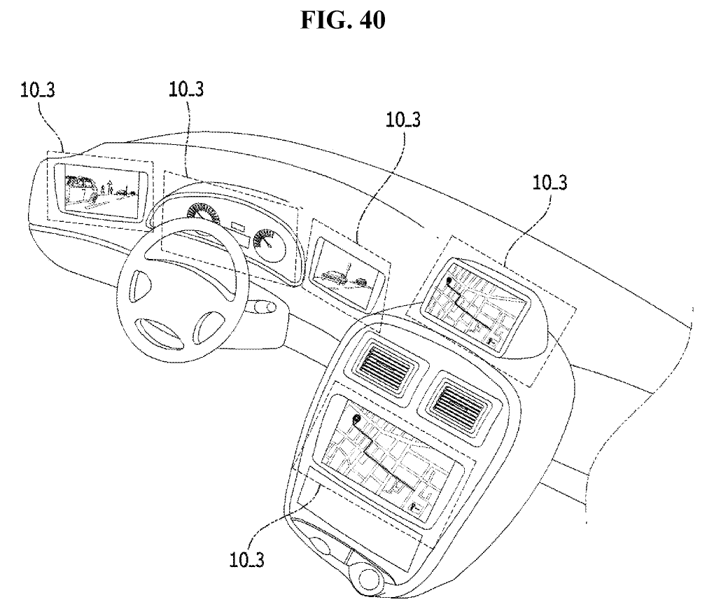

FIG. 40 illustrates a case in which an electronic device including a display module is applied to a vehicle. For example, an electronic device 10_3 may be applied to a vehicle's instrument panel or center fascia, or may be applied to a center information display (CID) placed on the vehicle's dashboard or a room mirror display that replaces a side mirror.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A display device comprising:
a substrate comprising a display area and a non-display area;
a pixel located in the display area of the substrate;
a trench located in the substrate, the trench overlapping a bending area of the non-display area of the substrate; and
a dummy layer located in or on the substrate to overlap the trench.

2. The display device of claim 1, wherein the dummy layer comprises a heating layer.

3. The display device of claim 1, wherein the dummy layer comprises amorphous silicon.

4. The display device of claim 1, wherein the substrate comprises:
a first base layer;
a barrier layer on the first base layer; and
a second base layer on the barrier layer.

5. The display device of claim 4, wherein the trench comprises a hole penetrating at least one of the first base layer, the barrier layer, or the second base layer.

6. The display device of claim 5, wherein the dummy layer overlaps the hole.

7. The display device of claim 6, wherein the hole penetrates the first base layer and the barrier layer, and
wherein the dummy layer is located on a bottom surface of the second base layer overlapping the hole.

8. The display device of claim 7, further comprising a planarization layer having a hole overlapping the dummy layer and located on the second base layer.

9. The display device of claim 8, further comprising a source pattern layer on the planarization layer and the second base layer.

10. The display device of claim 9, wherein the source pattern layer is located closer to the substrate in the bending area than in a peripheral area outside the bending area.

11. The display device of claim 8, wherein the hole of the planarization layer overlaps the hole of the substrate.

12. The display device of claim 6, further comprising a planarization layer located on the second base layer overlapping the hole,
wherein the hole penetrates the first base layer, the barrier layer, and the second base layer, and
wherein the dummy layer is located on a bottom surface of the planarization layer overlapping the hole.

13. The display device of claim 12, further comprising a source pattern layer located on the planarization layer overlapping the bending area.

14. The display device of claim 1,
further comprising:
a first planarization layer located on the substrate in the bending area;
a source pattern layer located on the first planarization layer in the bending area;
a second planarization layer located on the source pattern layer in the bending area;
a third planarization layer located on the second planarization layer in the bending area;
a pixel defining layer located on the third planarization layer in the bending area; and
a spacer located on the pixel defining layer in the bending area.

15. The display device of claim 14, further comprising at least one inorganic layer located on the spacer in the bending area.

16. The display device of claim 15, wherein the at least one inorganic layer is formed integrally with an inorganic layer of an encapsulation layer on the display area and the non-display area.

17. The display device of claim 14, further comprising at least one organic layer located on the spacer in the bending area.

18. An electronic device comprising:
a display device having a display screen,
wherein the display device comprises:
a substrate comprising a display area and a non-display area;
a pixel located in the display area of the substrate;
a trench located in the substrate, the trench overlapping a bending area of the non-display area of the substrate; and
a dummy layer located in or on the substrate overlapping the trench.

19. The electronic device of claim 18, wherein the dummy layer comprises a heating layer.

20. The electronic device of claim 18, wherein the electronic device comprises a smartphone, a tablet, a laptop, a TV, a desktop monitor, smart glasses, a smart watch, a head mounted display, and a vehicle.
